(19) United States
(12) Patent Application Publication
(10) Pub. No.: US 2026/0206458 A1
(43) Pub. Date: Jul. 16, 2026

(54) DISPLAY DEVICE, ELECTRONIC DEVICE, AND METHOD OF FABRICATING THE DISPLAY DEVICE

(71) Applicant: Samsung Display Co., Ltd., Yongin-si (KR)

(72) Inventor: Chun Gi YOU, Yongin-si (KR)

(21) Appl. No.: 19/406,483

(22) Filed: Dec. 2, 2025

(30) Foreign Application Priority Data
Jan. 14, 2025 (KR) 10-2025-0005628

(51) Int. Cl. H10K 59/80; H10K 59/12; H10K 59/122

(52) U.S. Cl. CPC H10K 59/80518; H10K 59/1201; H10K 59/122; H10K 59/80516

(57) ABSTRACT

A display device includes: a substrate; an insulating layer on the substrate, and having a via hole in which a via electrode is located; a connection electrode on the via electrode; a reflective electrode on the connection electrode; an optical auxiliary layer on the reflective electrode and the connection electrode; a first electrode on the optical auxiliary layer and the connection electrode; a pixel defining layer on the first electrode and the insulating layer to define an emission area exposing the first electrode; a light emitting stack on the first electrode and the pixel defining layer; and a second electrode on the light emitting stack. The optical auxiliary layer is located on an upper surface of the reflective electrode and side surfaces of the reflective electrode, and the first electrode is located on side surfaces of the connection electrode to be connected to the side surfaces of the connection electrode.

### CROSS-REFERENCE TO RELATED APPLICATION

The present application claims priority to and the benefit of Korean Patent Application No. 10-2025-0005628, filed on Jan. 14, 2025, in the Korean Intellectual Property Office, the entire disclosure of which is incorporated herein by reference.

### BACKGROUND

### 1. Field

One or more embodiments of the present disclosure relate to a display device, for example, to a display device capable of preventing or reducing a reflective electrode from being damaged, an electronic device including the display device, and a method of fabricating the display device.

### 2. Description of the Related Art

An organic light emitting display apparatus may include a display element that includes organic light emitting diodes, whose luminance varies according to an electric current.

### SUMMARY

One or more aspects of embodiments of the present disclosure are directed toward a display device capable of preventing or reducing a reflective electrode from being damaged, an electronic device, and a method of fabricating a display device. Additional aspects will be set forth in part in the description which follows and, in part, will be apparent from the description, or may be learned by practice of the presented embodiments of the disclosure.

According to one or more embodiments of the present disclosure, a display device includes: a substrate; an insulating layer on (e.g., arranged on) the substrate, and having a via hole in which a via electrode is located; a connection electrode on the via electrode; a reflective electrode on the connection electrode; an optical auxiliary layer on the reflective electrode and the connection electrode; a first electrode on the optical auxiliary layer and the connection electrode; a pixel defining layer on (e.g., arranged on) the first electrode and the insulating layer to define an emission area exposing the first electrode; a light emitting stack on the first electrode and the pixel defining layer; and a second electrode on the light emitting stack, wherein the optical auxiliary layer is located on an upper surface of the reflective electrode and a side surface of the reflective electrode, and the first electrode is located on a side surface of the connection electrode to be connected to the side surface of the connection electrode.

According to one or more embodiments of the present disclosure, an electronic device includes a display device that includes (e.g., displays) a display screen. The display device includes: a substrate; an insulating layer on (e.g., arranged on) the substrate, and having a via hole in which a via electrode is located; a connection electrode on the via electrode; a reflective electrode on the connection electrode; an optical auxiliary layer on the reflective electrode and the connection electrode; a first electrode on the optical auxiliary layer and the connection electrode; a pixel defining layer on (e.g., arranged on) the first electrode and the insulating layer to define an emission area exposing the first electrode; a light emitting stack on the first electrode and the pixel defining layer; and a second electrode on the light emitting stack, wherein the optical auxiliary layer is located on an upper surface of the reflective electrode and a side surface of the reflective electrode, and the first electrode is located on a side surface of the connection electrode to be connected to the side surface of the connection electrode.

According to one or more embodiments of the present disclosure, there is provided a method of fabricating a display device, the method including: forming, on a substrate, an insulating layer on which via electrodes are located; forming, on the insulating layer, a connection electrode layer connected to the via electrodes; forming a reflective electrode layer on the connection electrode layer; forming a buffer layer on the reflective electrode layer; exposing the reflective electrode layer on the reflective electrode layer of a first subpixel, a second subpixel, and a third subpixel by patterning the buffer layer; forming a first auxiliary layer on the reflective electrode layer; forming a first auxiliary pattern on the reflective electrode layer of the third subpixel by patterning the first auxiliary layer; forming a second auxiliary layer on the reflective electrode layer and the first auxiliary pattern; forming a second auxiliary pattern on each of the reflective electrode layer of the second subpixel and the first auxiliary pattern of the third subpixel by patterning the second auxiliary layer; forming a reflective electrode of the first subpixel on the connection electrode layer of the first subpixel, forming a reflective electrode of the second subpixel between the connection electrode layer of the second subpixel and the second auxiliary pattern of the second subpixel, and forming a reflective electrode of the third subpixel between the connection electrode layer of the third subpixel and the first auxiliary pattern of the third subpixel, by patterning the reflective electrode layer; forming a third auxiliary layer on the reflective electrodes, the connection electrode layer, and the second auxiliary pattern; forming connection electrodes of the first to third subpixels and forming a third auxiliary pattern on each of the reflective electrode of the first subpixel, the second auxiliary pattern of the second subpixel, and the second auxiliary pattern of the third subpixel by patterning the connection electrode layer and the third auxiliary layer, thereby forming optical auxiliary layers having different thicknesses in the first to third subpixels and covering an upper surface and a side surface of each reflective electrode; forming a first electrode layer on the optical auxiliary layers and the insulating layer; forming first electrodes on each upper surface of the optical auxiliary layers, each side surface of the optical auxiliary layers, and each side surface of the connection electrodes by patterning the first electrode layer; forming a defining layer on the first electrodes and the insulating layer; and washing the substrate including the first electrodes.

For example, in the display device according to embodiments of the present disclosure, the optical auxiliary layer is strategically positioned to cover both the upper surface and the side surface of the reflective electrode, thereby enhancing optical performance and protecting the reflective electrode from potential damage during subsequent fabrication processes. This configuration also facilitates improved light extraction and uniformity across the emission area. Furthermore, the first electrode is formed to extend along the side surface of the connection electrode, ensuring reliable electrical connectivity and structural integration between the first electrode and the underlying conductive layers. This arrangement contributes to the overall durability and efficiency of the display device, particularly in high-resolution or high-brightness applications where precise electrode alignment and protection of reflective components are important.

### ADVANTAGEOUS EFFECTS

According to one or more embodiments, a reflective electrode may be prevented or reduced from being damaged by hydrogen fluoride used in a washing process.

For example, according to one or more embodiments, because an optical auxiliary layer is arranged between a reflective electrode and a first electrode, a portion of the swollen reflective electrode may not pass through a pin hole of the first electrode. Accordingly, hydrogen fluoride used in the washing process after forming the first electrode may not permeate the reflective electrode. Therefore, according to one or more embodiments, even in the washing process, a damage of the reflective electrode may be prevented or reduced by the optical auxiliary layer.

The effects and benefit of the present disclosure are not limited to the above-described effects and other effects which are not described herein will become apparent to those skilled in the art from the following description or from learning by practicing the present disclosure.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. These and/or other aspects will become apparent and more readily appreciated from the following description of the example embodiments, taken in conjunction with the accompanying drawings in which:

FIG. 1 is an exploded perspective view of a display device according to one or more embodiments of the present disclosure;

FIG. 2 is a block diagram of a display device according to one or more embodiments of the present disclosure;

FIG. 3 is an equivalent circuit diagram of a first subpixel according to one or more embodiments of the present disclosure;

FIG. 4 is a layout view of an example of a display panel according to one or more embodiments of the present disclosure;

FIG. 5 and FIG. 6 are each a layout view of an example of the display area of FIG. 4 according to one or more embodiments of the present disclosure;

FIG. 7 is a cross-sectional view of an example of the display panel taken along the line I1-I1′ of FIG. 5 according to one or more embodiments of the present disclosure;

FIG. 8 is a detailed cross-sectional view of area A1 of FIG. 7 according to one or more embodiments of the present disclosure;

FIG. 9 is a detailed cross-sectional view of area A2 of FIG. 8 according to one or more embodiments of the present disclosure;

FIG. 10 is a cross-sectional view of an example of the display panel taken along the line I2-I2′ of FIG. 4 according to one or more embodiments of the present disclosure;

FIG. 11 is a detailed cross-sectional view of area A3 of FIG. 10 according to one or more embodiments of the present disclosure;

FIGS. 12, 13, 14, 15, 16, 17, 18, 19, 20, 21, 22, 23, 24, 25, 26, 27, and 28 are process cross-sectional views illustrating a method of fabricating a display device according to one or more embodiments of the present disclosure;

FIG. 29 is a block diagram of an electronic device according to one or more embodiments of the present disclosure; and

FIGS. 30, 31, and 32 are each a schematic diagram illustrating electronic devices according to one or more embodiments of the present disclosure.

### DETAILED DESCRIPTION

The present disclosure will now be described more fully hereinafter with reference to the accompanying drawings, in which example embodiments of the disclosure are shown. The disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that if (e.g., when) a layer is referred to as being “on” another layer or substrate, it may be directly on the other layer or substrate, or one or more intervening layers may also be present therebetween. In contrast, “directly on” may refer to that there are no additional intervening elements or layers between the element or layer and the another element or layer. The same or like reference numbers indicate the same or like components throughout the disclosure. In the accompanied drawings, the thickness of layers and regions may be exaggerated for clarity.

Although the terms “first”, “second”, and/or the like may be used herein to describe one or more suitable elements, these elements, should not be limited by these terms. These terms may be used to distinguish one element from another element. Thus, a first element discussed herein may be termed a second element without departing from teachings of one or more embodiments. The description of an element as a “first” element may not require or imply the presence of a second element or other elements. The terms “first”, “second”, and/or the like may also be used herein to differentiate different categories or sets of elements. For conciseness, in one or more embodiments, the terms “first”, “second”, and/or the like may represent “first-category (or first-set)”, “second-category (or second-set)”, and/or the like, respectively.

Features of one or more suitable embodiments of the present disclosure may be combined partially or totally. As will be clearly appreciated by those skilled in the art, technically one or more suitable interactions and operations are possible. Various embodiments may be practiced individually or in combination.

Hereinafter, one or more embodiments of the present disclosure will be described with reference to the accompanying drawings.

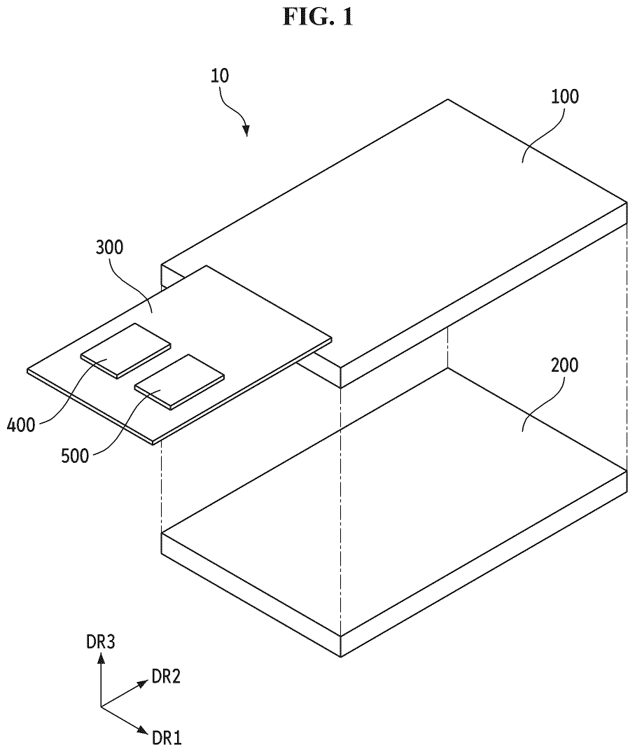

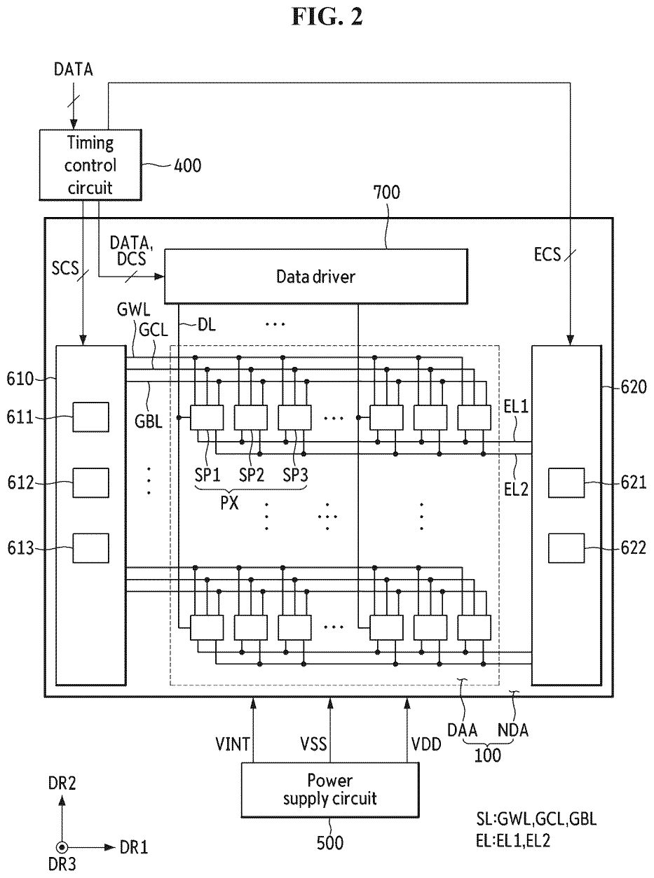

FIG. 1 is an exploded perspective view of a display device according to one or more embodiments of the present disclosure. FIG. 2 is a block diagram of the display device of FIG. 1 according to one or more embodiments of the present disclosure.

Referring to FIG. 1 and FIG. 2, a display device 10 according to one or more embodiments is a device for displaying moving images or still images. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra-mobile PCs (UMPCs). For example, the display device 10 according to one or more embodiments may be applied as a display unit of a television, a notebook computer, a monitor, a billboard, or an Internet of things (IoT) device. In one or more embodiments, the display device 10 may be applied to smart watches, watch phones, and/or head mounted displays for implementing virtual reality and augmented reality.

The display device 10 according to one or more embodiments may include a display panel 100, a heat dissipation layer 200, a circuit board 300, a timing control circuit 400, and a power supply circuit 500.

In one or more embodiments, the display panel 100 may have a planar shape, for example, similar to a quadrangle. For example, the display panel 100 may have a planar shape, similar to a quadrangle, that has short sides in a first direction DR1 and long sides in a second direction DR2 intersecting the first direction DR1. In the display panel 100, each corner where the short side extending in the first direction DR1 meets the long side extending in the second direction DR2 may be rounded with a set or predetermined curvature or may be right-angled. The planar shape of the display panel 100 is not limited to a quadrangular shape and may also be a shape similar to other polygonal shape(s), a circular shape, or an oval shape. A planar shape of the display device 10 may follow the planar shape of the display panel 100, but embodiments of the present specification are not limited thereto.

The display panel 100 includes a plurality of pixels PX, a plurality of scan lines SL, a plurality of emission control lines EL, a plurality of data lines DL, a scan driver 610, an emission driver 620, and a data driver 700. As illustrated in FIG. 2, the display panel 100 may be divided into a display area DAA displaying an image and a non-display area NDA not displaying an image.

The pixels PX may be arranged in the display area DAA. The pixels PX may be arranged in a matrix form in the first direction DR1 and the second direction DR2. In one or more embodiments, the scan lines SL and the emission control lines EL may extend in the first direction DR1 and may be arranged in the second direction DR2. The data lines DL may extend in the second direction DR2 and may be arranged in the first direction DR1.

The scan lines SL include a plurality of write scan lines GWL, a plurality of control scan lines GCL, and a plurality of bias scan lines GBL. The emission control lines EL include a plurality of first emission control lines EL1 and a plurality of second emission control lines EL2.

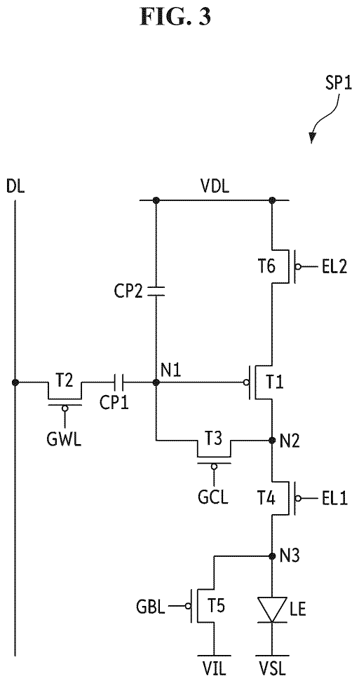

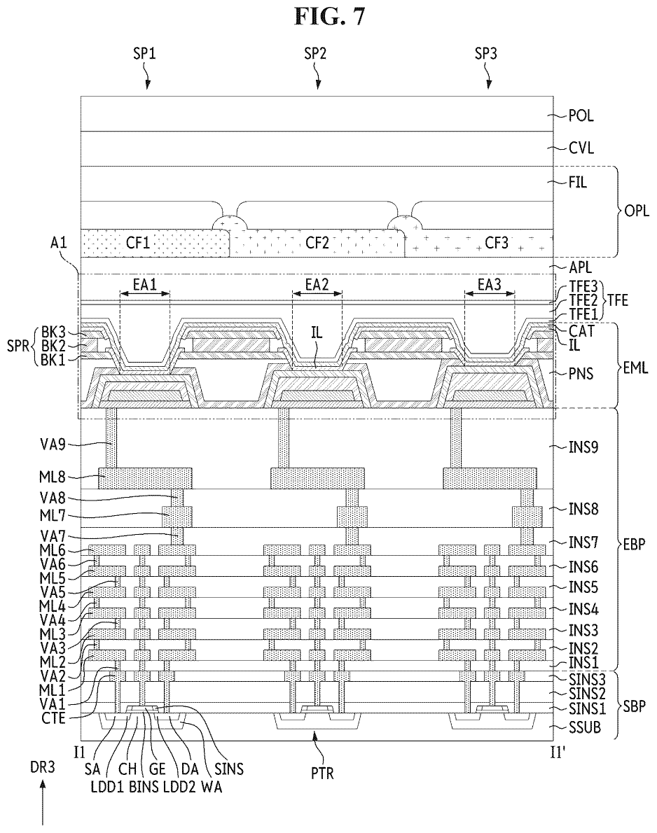

Each of the pixels PX includes a plurality of subpixels SP1 through SP3. Each of the subpixels SP1 through SP3 may include a plurality of pixel transistors as illustrated in FIG. 3. The pixel transistors may be formed through a semiconductor process and may be located in a semiconductor substrate SSUB (see FIG. 7). For example, in one or more embodiments, a plurality of pixel transistors of the data driver 700 may be formed as complementary metal oxide semiconductor (CMOS) transistors, but embodiments of the present specification are not limited thereto.

Each of the subpixels SP1 through SP3 may be connected to one (e.g., any one) of the write scan lines GWL, one (e.g., any one) of the control scan lines GCL, one (e.g., any one) of the bias scan lines GBL, one (e.g., any one) of the first emission control lines EL1, one (e.g., any one) of the second emission control lines EL2, and one (e.g., any one) of the data lines DL. Each of the subpixels SP1 through SP3 may receive a data voltage of a data line DL according to a write scan signal of a write scan line GWL and emit light from a light emitting element according to the data voltage.

In one or more embodiments, the scan driver 610, the emission driver 620, and the data driver 700 may be located in the non-display area NDA.

The scan driver 610 includes a plurality of scan transistors, and the emission driver 620 includes a plurality of emission transistors. The scan transistors and the emission transistors may be formed through a semiconductor process and may be formed in the semiconductor substrate SSUB (see FIG. 7). For example, in one or more embodiments, the scan transistors and the emission transistors may be formed as CMOS transistors, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The emission driver 620 includes a first emission control driving unit 621 and a second emission control driving unit 622. Each of the first emission control driving unit 621 and the second emission control driving unit 622 may receive an emission timing control signal ECS from the timing control circuit 400. The first emission control driving unit 621 may generate first emission control signals according to the emission timing control signal ECS and sequentially output the first emission control signals to the first emission control lines EL1. The second emission control driving unit 622 may generate second emission control signals according to the emission timing control signal ECS and sequentially output the second emission control signals to the second emission control lines EL2.

The data driver 700 includes a plurality of data transistors. The data transistors may be formed through a semiconductor process and may be formed in the semiconductor substrate SSUB (see FIG. 7). For example, in one or more embodiments, the data transistors may be formed as CMOS transistors, but embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this regard, subpixels SP1 through SP3 may be selected by a write scan signal of the scan driver 610, and the data voltages (e.g., analog data voltages) may be supplied to the selected subpixels SP1 through SP3.

The heat dissipation layer 200 may overlap the display panel 100 in a third direction DR3 which is a thickness direction of the display panel 100. The heat dissipation layer 200 may be located on a surface, e.g., a back surface of the display panel 100. The heat dissipation layer 200 dissipates heat generated from the display panel 100. The heat dissipation layer 200 may include a metal layer having high thermal conductivity, such as graphite, silver (Ag), copper (Cu), and/or aluminum (Al).

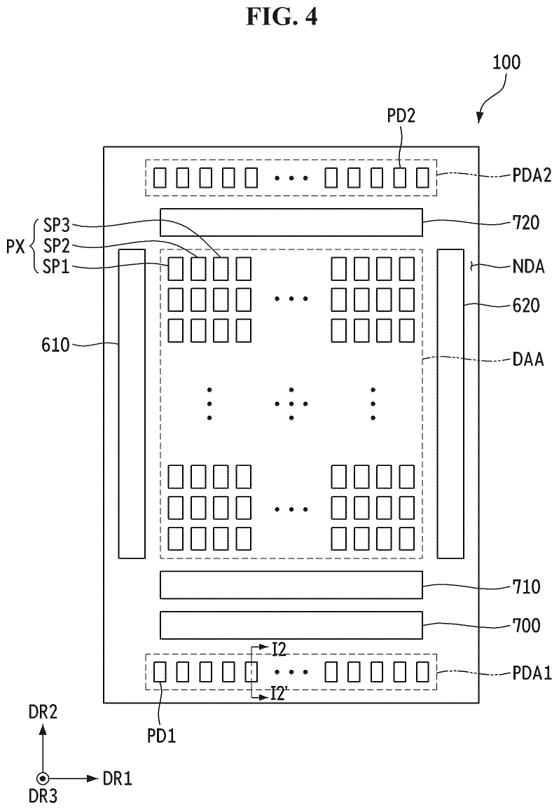

The circuit board 300 may be electrically connected to a plurality of first pads PD1 (see FIG. 4) in a first pad portion PDA1 (see FIG. 4) of the display panel 100 by using a conductive adhesive member such as an anisotropic conductive film. In one or more embodiments, the circuit board 300 may be a flexible printed circuit board or a flexible film. Although the circuit board 300 is unfolded in FIG. 1, it may also be bent. In this regard, one end of the circuit board 300 may be placed on the back surface of the display panel 100 and/or a back surface of the heat dissipation layer 200. The other end of the circuit board 300 may be connected to the first pads PD1 (see FIG. 4) of the first pad portion PDA1 (see FIG. 4) of the display panel 100 by using a conductive adhesive member. The one end of the circuit board 300 may be an end opposite the other end of the circuit board 300.

The timing control circuit 400 may receive digital video data and timing signals from the outside. The timing control circuit 400 may generate the scan timing control signal SCS, the emission timing control signal ECS, and the data timing control signal DCS for controlling the display panel 100 according to the timing signals. The timing control circuit 400 may output the scan timing control signal SCS to the scan driver 610 and the emission timing control signal ECS to the emission driver 620. The timing control circuit 400 may output the digital video data DATA and the data timing control signal DCS to the data driver 700.

The power supply circuit 500 may generate a plurality of panel driving voltages according to a power supply voltage received from the outside. For example, in one or more embodiments, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later with reference to FIG. 3.

Each of the timing control circuit 400 and the power supply circuit 500 may be formed as an integrated circuit and attached to a surface of the circuit board 300. In this regard, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

In one or more embodiments, the timing control circuit 400 and the power supply circuit 500 may be located in the non-display area NDA of the display panel 100, like the scan driver 610, the emission driver 620, and the data driver 700. In these embodiments, the timing control circuit 400 may include a plurality of timing transistors, and the power supply circuit 500 may include a plurality of power transistors. The timing transistors and the power transistors may be formed through a semiconductor process and may be formed in the semiconductor substrate SSUB (see FIG. 7). For example, in one or more embodiments, the timing transistors and the power transistors may be formed as CMOS transistors, but embodiments of the present disclosure are not limited thereto. In one or more embodiments, each of the timing control circuit 400 and the power supply circuit 500 may be located between the data driver 700 and the first pad portion PDA1 (see FIG. 4).

FIG. 3 is an equivalent circuit diagram of a first subpixel according to one or more embodiments of the present disclosure.

Referring to FIG. 3, the first subpixel SP1 may be connected to a write scan line GWL, a control scan line GCL, a bias scan line GBL, a first emission control line EL1, a second emission control line EL2, and a data line DL. In addition, the first subpixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, in one or more embodiments, the first driving voltage line VSL may be a low-potential voltage line, the second driving voltage line VDL may be a high-potential voltage line, and the third driving voltage line VIL may be an initialization voltage line. Here, the first driving voltage VSS may be lower than the third driving voltage VINT. The second driving voltage VDD may be higher than the third driving voltage VINT.

In one or more embodiments, the first subpixel SP1 includes a plurality of transistors T1 through T6, a light emitting element LE, a first capacitor CP1, and a second capacitor CP2.

The light emitting element LE emits light according to a driving current flowing through a channel of a first transistor T1. The amount (e.g., emission intensity) of light emitted from the light emitting element LE may be proportional to the driving current. The light emitting element LE may be located between a fourth transistor T4 and the first driving voltage line VSL. A first electrode of the light emitting element LE may be connected to a drain electrode of the fourth transistor T4, and a second electrode of the light emitting element LE may be connected to the first driving voltage line VSL. The first electrode of the light emitting element LE may be an anode, and the second electrode of the light emitting element LE may be a cathode. In one or more embodiments, the light emitting element LE may be an organic light emitting diode including a first electrode, a second electrode, and an organic light emitting layer located between the first electrode and the second electrode. However, embodiments of the present disclosure are not limited thereto. For example, in one or more embodiments, the light emitting element LE may be an inorganic light emitting element including a first electrode, a second electrode, and an inorganic semiconductor located between the first electrode and the second electrode. In these embodiments, the light emitting element LE may be a micro light emitting diode.

The first transistor T1 may be a driving transistor that controls a source-drain current (hereinafter, referred to as a “driving current”) flowing between a source electrode and a drain electrode according to a voltage applied to a gate electrode. The first transistor T1 includes the gate electrode connected to a first node N1, the source electrode connected to a drain electrode of a sixth transistor T6, and the drain electrode connected to a second node N2.

A second transistor T2 may be located between one electrode of the first capacitor CP1 and the data line DL. The second transistor T2 is turned on by a write scan signal of the write scan line GWL and connects the one electrode of the first capacitor CP1 to the data line DL. Accordingly, a data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

A third transistor T3 may be located between the first node N1 and the second node N2. The third transistor T3 is turned on by a write control signal of the write control line GCL and connects the first node N1 to the second node N2. Accordingly, if (e.g., when) the gate electrode and the drain electrode of the first transistor T1 are connected, the first transistor T1 may operate as a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by a first emission control signal of the first emission control line EL1 and connects the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and the drain electrode connected to the third node N3.

A fifth transistor T5 may be located between the third node N3 and the third driving voltage line VIL. The fifth transistor T5 is turned on by a bias scan signal of the bias scan line GBL and connects the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line GBL, a source electrode connected to the third node N3, and a drain electrode connected to the third driving voltage line VIL.

The sixth transistor T6 may be located between the source electrode of the first transistor T1 and the second driving voltage line VDL. The sixth transistor T6 is turned on by a second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and the drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point between the gate electrode of the first transistor T1, the drain electrode of the third transistor T3, the other electrode of the first capacitor CP1, and the one electrode of the second capacitor CP2. The second node N2 is a contact point between the drain electrode of the first transistor T1, the source electrode of the third transistor T3, and the source electrode of the fourth transistor T4. The third node N3 is a contact point between the drain electrode of the fourth transistor T4, the source electrode of the fifth transistor T5, and the first electrode of the light emitting element LE.

Each of the first through sixth transistors T1 through T6 may be a metal-oxide-semiconductor field effect transistor (MOSFET). For example, in one or more embodiments, each of the first through sixth transistors T1 through T6 may be a P-type (kind) MOSFET. However, embodiments of the present disclosure are not limited thereto. For example, in one or more embodiments, each of the first through sixth transistors T1 through T6 may be an N-type (kind) MOSFET. In one or more embodiments, some of the first through sixth transistors T1 through T6 may be P-type (kind) MOSFETs, and the other transistors may be N-type (kind) MOSFETs.

In FIG. 3, the first subpixel SP1 includes six transistors T1 through T6 and two capacitors CP1 and CP2. However, it should be noted that the equivalent circuit diagram of the first subpixel SP1 is not limited to that illustrated in FIG. 3. For example, the number of transistors and the number of capacitors in the first subpixel SP1 are not limited to those illustrated in FIG. 3.

In addition, an equivalent circuit diagram of the second subpixel SP2 and an equivalent circuit diagram of the third subpixel SP3 may each be substantially the same as the equivalent circuit diagram of the first subpixel SP1 described with reference to FIG. 3. Therefore, the equivalent circuit diagram of the second subpixel SP2 and the equivalent circuit diagram of the third subpixel SP3 will not be described in the present disclosure.

FIG. 4 is a layout view of an example of a display panel according to one or more embodiments of the present disclosure.

Referring to FIG. 4, a display area DAA of the display panel 100 according to one or more embodiments includes a plurality of pixels PX arranged in a matrix form. A non-display area NDA of the display panel 100 according to one or more embodiments includes a scan driver 610, an emission driver 620, a data driver 700, a first distribution circuit 710, a second distribution circuit 720, a first pad portion PDA1, and a second pad portion PDA2.

The scan driver 610 may be located on a first side of the display area DAA, and the emission driver 620 may be located on a second side (e.g., opposite the first side) of the display area DAA. For example, the scan driver 610 may be located on one side of the display area DAA in the first direction DR1, and the emission driver 620 may be located on the other side of the display area DAA in the first direction DR1. For example, the scan driver 610 may be located on a left side of the display area DAA, and the emission driver 620 may be located on a right side of the display area DAA, as shown in FIG. 4. However, embodiments of the present disclosure are not limited thereto, for example, in one or more embodiments, the scan driver 610 and the emission driver 620 may also be located on both (e.g., simultaneously) the first side and the second side of the display area DAA.

The first pad portion PDA1 may include a plurality of first pads PD1 connected to pads or bumps of the circuit board 300 through a conductive adhesive member. The first pad portion PDA1 may be located on a third side of the display area DAA. For example, in one or more embodiments, the first pad portion PDA1 may be located on one side of the display area DAA in the second direction DR2. The first pad portion PDA1 may be located outside the data driver 700 in the second direction DR2. For example, the first pad portion PDA1 may be located closer to an edge of the display panel 100 than the data driver 700. In other words, the first pad portion PDA1 may be arranged such that it lies between the data driver 700 and the edge (outer boundary) of the display panel 100 in the second direction DR2.

The second pad portion PDA2 may include a plurality of second pads PD2 corresponding to inspection pads for inspecting whether the display panel 100 operates normally. The second pads PD2 may be connected to a jig or a probe pin during an inspection process or may be connected to a circuit board for inspection. The circuit board for inspection may be a rigid printed circuit board or a flexible printed circuit board.

The second pad portion PDA2 may be located on a fourth side of the display area DAA. For example, in one or more embodiments, the second pad portion PDA2 may be located on the other side of the display area DAA in the second direction DR2. The second pad portion PDA2 may be located outside the second distribution circuit 720 in the second direction DR2. For example, the second pad portion PDA2 may be located closer to an edge of the display panel 100 than the second distribution circuit 720.

The first distribution circuit 710 distributes data voltages received through the first pad portion PDA1 to a plurality of data lines DL. For example, in one or more embodiments, the first distribution circuit 710 may distribute data voltages received through one first pad PD1 of the first pad portion PDA1 to P (P is a positive integer of 2 or greater) data lines DL. Therefore, the number of first pads PD1 can be reduced. The first distribution circuit 710 may be located on the third side of the display area DAA of the display panel 100. For example, the first distribution circuit 710 may be located on one side of the display area DAA in the second direction DR2. For example, the first distribution circuit 710 may be located on a lower side of the display area DAA.

The second distribution circuit 720 distributes signals received through the second pad portion PDA2 to the scan driver 610, the emission driver 620, and the data lines DL. The second pad portion PDA2 and the second distribution circuit 720 may be elements for inspecting the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2. For example, the second distribution circuit 720 may be located on an upper side of the display area DAA.

In the context of the present disclosure and unless defined otherwise, “one side of the display area DAA in the second direction DR2” refers to a specific side of the display area along the direction labeled as DR2. For instance, if DR2 represents a vertical direction, this may indicate the bottom side of the display area. Conversely, “the other side of the display area DAA in the second direction DR2” refers to the opposite side of the display area along the same direction DR2, which, continuing the previous example, may indicate the top side of the display area. These phrases are used to describe the positioning of components, such as distribution circuits, on opposite sides of the display area along the specified direction DR2.

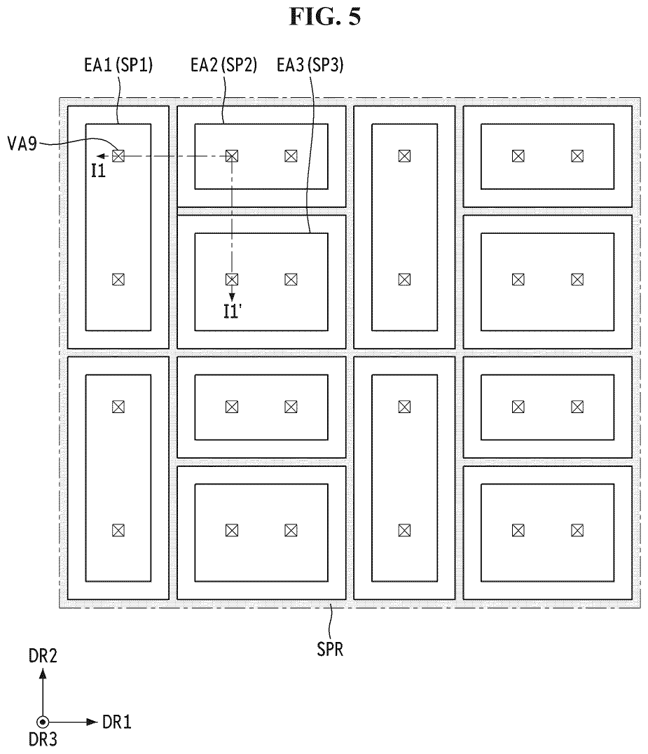

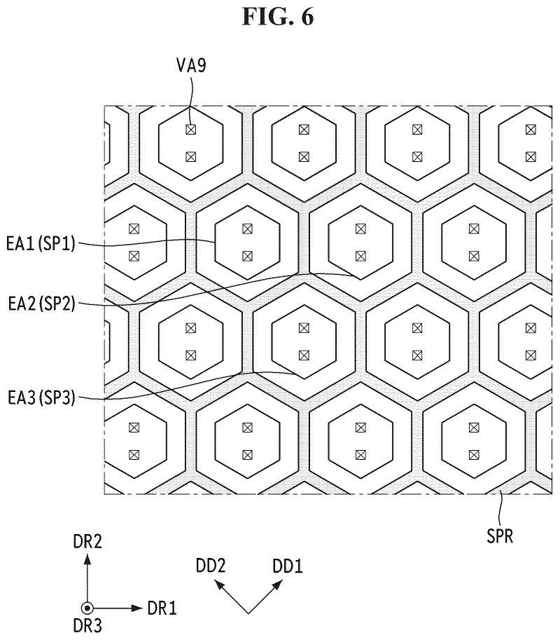

FIG. 5 and FIG. 6 are each a layout view of an embodiment of the display area of FIG. 4.

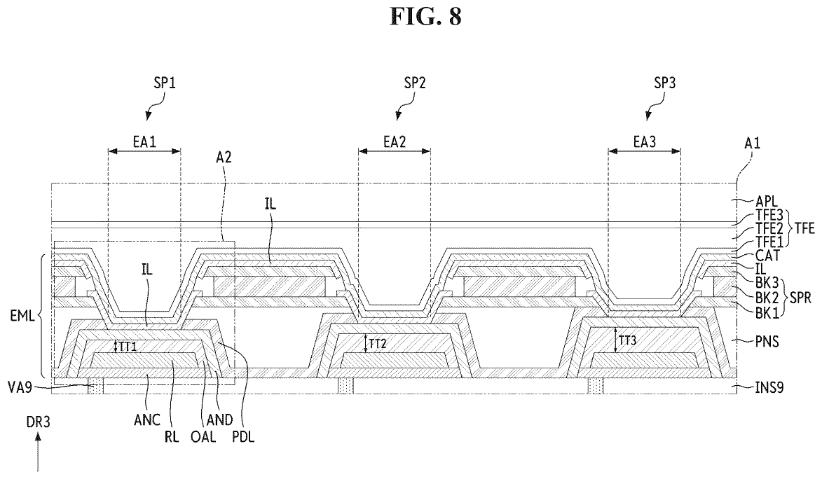

Referring to FIG. 5 and FIG. 6, each of a plurality of pixels PX includes a first emission area EA1 which is an emission area of the first subpixel SP1, a second emission area EA2 which is an emission area of the second subpixel SP2, and a third emission area EA3 which is an emission area of the third subpixel SP3. The first emission area EA1, the second emission area EA2, and the third emission area EA3 may be separated by a separator SPR, and each of the first emission area EA1, the second emission area EA2, and the third emission area EA3 may include a via VA9. The detailed descriptions of the separator SPR and the via VA9 will be described in more detail later with reference to FIG. 7 and FIG. 8.

Each of the first emission area EA1, the second emission area EA2, and the third emission area EA3 may have a polygonal shape, a circular shape, an oval shape, or irregular planar shape in plan view.

In one or more embodiments, a maximum length of the first emission area EA1 in the first direction DR1 may be smaller than a maximum length of the second emission area EA2 in the first direction DR1 and a maximum length of the third emission area EA3 in the first direction DR1. The maximum length of the second emission area EA2 in the first direction DR1 may be substantially equal to the maximum length of the third emission area EA3 in the first direction DR1.

A maximum length of the first emission area EA1 in the second direction DR2 may be greater than a maximum length of the second emission area EA2 in the second direction DR2 and a maximum length of the third emission area EA3 in the second direction DR2. The maximum length of the second emission area EA2 in the second direction DR2 may be smaller than the maximum length of the third emission area EA3 in the second direction DR2. The maximum length of the first emission area EA1 in the second direction DR2 may be greater than the maximum length of the second emission area EA2 in the second direction DR2.

The first emission area EA1, the second emission area EA2, and the third emission area EA3 may each have a quadrangular shape as illustrated in FIG. 5 or a hexagonal shape as illustrated in FIG. 6. However, embodiments of the present disclosure are not limited thereto. In one or more embodiments, the first emission area EA1, the second emission area EA2, and the third emission area EA3 may each independently have a polygonal planar shape other than a hexagonal shape, or an oval shape, or an irregular planar shape.

As illustrated in FIG. 5, in each of the pixels PX, the first emission area EA1 and the second emission area EA2 may neighbor each other in the first direction DR1. In addition, the first emission area EA1 and the third emission area EA3 may neighbor each other in the first direction DR1. In addition, the second emission area EA2 and the third emission area EA3 may neighbor each other in the second direction DR2. The area of the first emission area EA1, the area of the second emission area EA2, and the area of the third emission area EA3 may be different.

In one or more embodiments, as illustrated in FIG. 6, the first emission area EA1 and the second emission area EA2 may neighbor each other in the first direction DR1. However, the second emission area EA2 and the third emission area EA3 may neighbor each other in a first diagonal direction DD1, and the first emission area EA1 and the third emission area EA3 may neighbor each other in a second diagonal direction DD2. The first diagonal direction DD1 may be a direction between the first direction DR1 and the second direction DR2 and a direction inclined at 45 degrees with respect to the first direction DR1 and the second direction DR2. The second diagonal direction DD2 may be a direction orthogonal to the first diagonal direction DD1.

The first subpixel SP1 may output first light that has passed through a first color filter CF1 (see FIG. 7) among light emitted from the first emission area EA1, the second subpixel SP2 may output second light that has passed through a second color filter CF2 (see FIG. 7) among light emitted from the second emission area EA2, and the third subpixel SP3 may output third light that has passed through a third color filter CF3 (see FIG. 7) among light emitted from the third emission area EA3.

The first light, the second light, and the third light may be light of different wavelength bands. For example, in one or more embodiments, any one selected from among the first light, the second light, and the third light may be light in a blue wavelength band, another may be light in a green wavelength band, and the other may be light in a red wavelength band. Here, the blue wavelength band may indicate that a main peak wavelength of light is included in a wavelength band of about 370 nm to about 460 nm, the green wavelength band may indicate that a main peak wavelength of light is included in a wavelength band of about 480 nm to about 560 nm, and the red wavelength band may indicate that a main peak wavelength of light is included in a wavelength band of about 600 nm to about 750 nm.

Although each of the pixels PX includes three emission areas EA1 through EA3 in FIG. 5 and FIG. 6, embodiments of the present disclosure are not limited thereto. For example, in one or more embodiments, each of the pixels PX may include four emission areas.

In addition, the arrangement of the emission areas of the pixels PX is not limited to those illustrated in FIG. 5 and FIG. 6. For example, in one or more embodiments, the emission areas of the pixels PX may be arranged in a stripe structure in which emission areas are arranged in the first direction DR1, in a PenTile® structure in which emission areas are arranged in a diamond shape, or in a hexagonal structure in which emission areas having a hexagonal planar shape are arranged as illustrated in FIG. 6. PenTile® is a duly registered trademark of Samsung Display Co., Ltd.

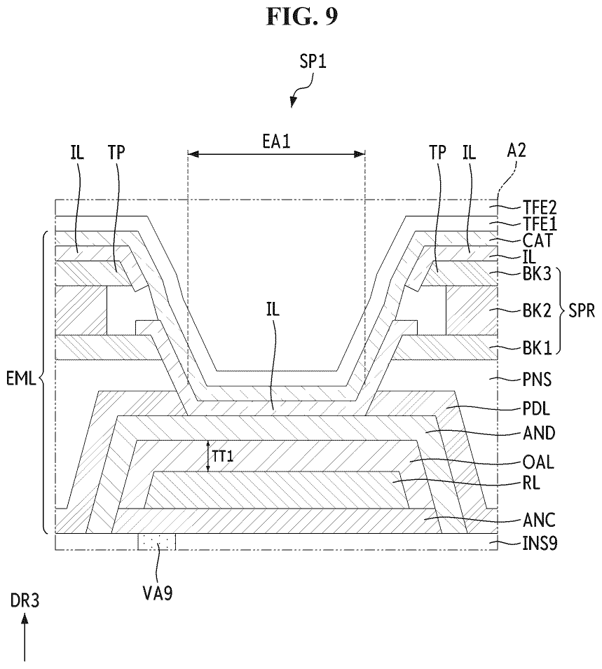

FIG. 7 is a cross-sectional view of an example of the display panel taken along the line I1-I1′ of FIG. 5 according to one or more embodiments. FIG. 8 is a detailed cross-sectional view of area A1 of FIG. 7 according to one or more embodiments. FIG. 9 is a detailed cross-sectional view of area A2 of FIG. 8 according to one or more embodiments.

Referring to FIGS. 7 through 9, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating layers covering the pixel transistors PTR, and a plurality of contact terminals CTE electrically connected to the pixel transistors PTR. The pixel transistors PTR may include (e.g., be) the first through sixth transistors T1 through T6 described with reference to FIG. 3.

The semiconductor substrate SSUB may be a silicon substrate, a germanium substrate, or a silicon-germanium substrate. The semiconductor substrate SSUB may be a substrate doped with first-type (kind) impurities. A plurality of well regions WA may be located in an upper surface of the semiconductor substrate SSUB. The well regions WA may each be an area doped with second-type (kind) impurities (e.g., dopants). The second-type (kind) impurities may be different from the first-type (kind) impurities described above. For example, in one or more embodiments, if (e.g., when) the first-type (kind) impurities are p-type (kind) impurities, the second-type (kind) impurities may be n-type (kind) impurities. In one or more embodiments, if (e.g., when) the first-type (kind) impurities are n-type (kind) impurities, the second-type (kind) impurities may be p-type (kind) impurities.

Each of the well regions WA includes a source region SA corresponding to a source electrode of a pixel transistor PTR, a drain region DA corresponding to a drain electrode of the pixel transistor PTR, and a channel region CH located between the source region SA and the drain region DA.

A bottom insulating layer BINS may be located between a gate electrode GE and each well region WA. A side insulating layer SINS may be located on side surfaces of the gate electrode GE. The side insulating layer SINS may be located on the bottom insulating layer BINS.

Each of the source region SA and the drain region DA may be an area doped with the first-type (kind) impurities. The gate electrode GE of each pixel transistor PTR may overlap a respective well region WA in the third direction DR3 which is a thickness direction of the semiconductor substrate SSUB. The channel region CH may overlap the respective gate electrode GE in the third direction DR3. The source region SA may be located on one side of the gate electrode GE, and the drain region DA may be located on the other side of the gate electrode GE.

Each of the well regions WA may further include a first lightly doped impurity region LDD1 located between the channel region CH and the source region SA and a second lightly doped impurity region LDD2 located between the channel region CH and the drain region DA. The first lightly doped impurity region LDD1 may be an area having a lower impurity concentration than the source region SA due to the bottom insulating layer BINS. The second lightly doped impurity region LDD2 may be an area having a lower impurity (e.g., dopant) concentration than the drain region DA due to the bottom insulating layer BINS. A distance between the source region SA and the drain region DA may be increased by the first lightly doped impurity region LDD1 and the second lightly doped impurity region LDD2. Accordingly, a length of the channel region CH of each pixel transistor PTR may increase, thereby preventing or reducing punch-through and hot carrier phenomena caused by a short channel.

A first semiconductor insulating layer SINS1 may be located on the semiconductor substrate SSUB. The first semiconductor insulating layer SINS1 may include a silicon carbon nitride (SiCN) layer or a silicon oxide (SiOₓ)-based inorganic layer, but embodiments of the present disclosure are not limited thereto.

A second semiconductor insulating layer SINS2 may be located on the first semiconductor insulating layer SINS1. The second semiconductor insulating layer SINS2 may include a silicon oxide (SiOₓ)-based inorganic layer, but embodiments of the present disclosure are not limited thereto.

The contact terminals CTE may be located on the second semiconductor insulating layer SINS2. Each of the contact terminals CTE may be connected to corresponding one of the gate electrode GE, the source region SA, and the drain region DA of a pixel transistor PTR through a hole penetrating the first semiconductor insulating layer SINS1 and the second semiconductor insulating layer SINS2. The contact terminals CTE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or may include an alloy or a compound including any one selected therefrom.

A third semiconductor insulating layer SINS3 may be located on side surfaces of each of the contact terminals CTE. An upper surface of each of the contact terminals CTE may be exposed without being covered by the third semiconductor insulating layer SINS3. The third semiconductor insulating layer SINS3 may include a silicon oxide (SiOₓ)-based inorganic layer, but embodiments of the present disclosure are not limited thereto.

In one or more embodiments, the semiconductor substrate SSUB may be replaced with a glass substrate or a polymer resin substrate such as polyimide. In these embodiments, thin-film transistors may be located on the glass substrate or the polymer resin substrate. The glass substrate may be a rigid substrate that is not bent, and the polymer resin substrate may be a flexible substrate that can be bent or curved.

The light emitting element backplane EBP may include a plurality of conductive layers ML1 through ML8, a plurality of via electrodes VA1 through VA9, and a plurality of insulating layers INS1 through INS9. In addition, the light emitting element backplane EBP includes a plurality of insulating layers INS1 through INS9 separately located between first through eighth conductive layers ML1 through ML8.

The first through eighth conductive layers ML1 through ML8 implement the circuit of the first subpixel SP1 illustrated in FIG. 3 by connecting the contact terminals CTE exposed in the semiconductor backplane SBP. For example, in one or more embodiments, the first through sixth transistors T1 through T6 are simply formed in the semiconductor backplane SBP, and the connection of the first through sixth transistors T1 through T6 and the first and second capacitors CP1 and CP2 are achieved through the first through eighth conductive layers ML1 through ML8. In addition, the connection between a drain region corresponding to the drain electrode of the fourth transistor T4, a source region corresponding to the source electrode of the fifth transistor T5, and a first electrode AND of the light emitting element LE is achieved through the first through eighth conductive layers ML1 through ML8.

A first insulating layer INS1 may be located on the semiconductor backplane SBP. First via electrodes VA1 may penetrate the first insulating layer INS1 and may be respectively connected to the contact terminals CTE exposed in the semiconductor backplane SBP. The first conductive layers ML1 may be located on the first insulating layer INS1 and may be connected to the first via electrodes VA1, respectively.

A second insulating layer INS2 may be located on the first insulating layer INS1 and the first conductive layers ML1. Second via electrodes VA2 may penetrate the second insulating layer INS2 and may be connected to the exposed first conductive layers ML1, respectively. The second conductive layers ML2 may be located on the second insulating layer INS2 and may be connected to the second via electrodes VA2, respectively.

A third insulating layer INS3 may be located on the second insulating layer INS2 and the second conductive layers ML2. Third via electrodes VA3 may penetrate the third insulating layer INS3 and may be connected to the exposed second conductive layers ML2, respectively. The third conductive layers ML3 may be located on the third insulating layer INS3 and may be connected to the third via electrodes VA3, respectively.

A fourth insulating layer INS4 may be located on the third insulating layer INS3 and the third conductive layers ML3. Fourth via electrodes VA4 may penetrate the fourth insulating layer INS4 and may be connected to the exposed third conductive layers ML3, respectively. The fourth conductive layers ML4 may be located on the fourth insulating layer INS4 and may be connected to the fourth via electrodes VA4, respectively.

A fifth insulating layer INS5 may be located on the fourth insulating layer INS4 and the fourth conductive layers ML4. Fifth via electrodes VA5 may penetrate the fifth insulating layer INS5 and may be connected to the exposed fourth conductive layers ML4, respectively. The fifth conductive layers ML5 may be located on the fifth insulating layer INS5 and may be connected to the fifth via electrodes VA5, respectively.

A sixth insulating layer INS6 may be located on the fifth insulating layer INS5 and the fifth conductive layers ML5. Sixth via electrodes VA6 may penetrate the sixth insulating layer INS6 and may be connected to the exposed fifth conductive layers ML5, respectively. The sixth conductive layers ML6 may be located on the sixth insulating layer INS6 and may be connected to the sixth via electrodes VA6, respectively.

A seventh insulating layer INS7 may be located on the sixth insulating layer INS6 and the sixth conductive layers ML6. Each of seventh via electrodes VA7 may penetrate the seventh insulating layer INS7 and may be connected to a respective exposed sixth conductive layer ML6. The seventh conductive layers ML7 may be located on the seventh insulating layer INS7 and may be connected to the seventh via electrodes VA7, respectively.

An eighth insulating layer INS8 may be located on the seventh insulating layer INS7 and the seventh conductive layers ML7. Eighth via electrodes VA8 may penetrate the eighth insulating layer INS8 and may be connected to the exposed seventh conductive layers ML7, respectively. The eighth conductive layers ML8 may be located on the eighth insulating layer INS8 and may be connected to the eighth via electrodes VA8, respectively.

The first through eighth conductive layers ML1 through ML8 and the first through eighth via electrodes VA1 through VA8 may include substantially a same material. In one or more embodiments, the first through eighth conductive layers ML1 through ML8 and the first through eighth via electrodes VA1 through VA8 may each include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or may include an alloy or a compound including any one selected therefrom. The first through eighth via electrodes VA1 through VA8 may include substantially the same material. The first through eighth insulating layers INS1 through INS8 may include a silicon oxide (SiOₓ)-based inorganic layer, but embodiments of the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via electrode VA1, the second via electrode VA2, the third via electrode VA3, the fourth via electrode VA4, the fifth via electrode VA5, and the sixth via electrode VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, in one or more embodiments, the thickness of the first conductive layer ML1 may be approximately (about) 1,360 angstroms (Å) (i.e., 10⁻¹⁰ m); the thickness of each of the second conductive layer ML2, the third conductive layer ML3, the fourth conductive layer ML4, the fifth conductive layer ML5, and the sixth conductive layer ML6 may be approximately (about) 1,440 Å; and the thickness of each of the first via electrode VA1, the second via electrode VA2, the third via electrode VA3, the fourth via electrode VA4, the fifth via electrode VA5, and the sixth via electrode VA6 may be approximately (about) 1,150 Å.

A thickness of the seventh conductive layer ML7 and a thickness of the eighth conductive layer ML8 may each be greater than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may each be greater than a thickness of the seventh via electrode VA7 and a thickness of the eighth via electrode VA8. The thickness of the seventh via electrode VA7 and the thickness of the eighth via electrode VA8 may each be greater than the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6. The thickness of the seventh conductive layer ML7 and the thickness of the eighth conductive layer ML8 may be substantially the same. For example, in one or more embodiments, the thickness of the seventh conductive layer ML7 and the thickness of the eighth conductive layer ML8 may each be about 9,000 Å. The thickness of the seventh via electrode VA7 and the thickness of the eighth via electrode VA8 may each be about 6,000 Å.

A ninth insulating layer INS9 may be located on the eighth insulating layer INS8 and the eighth conductive layer ML8. The ninth insulating layer INS9 may include a silicon oxide (SiOₓ)-based inorganic layer, but embodiments of the present disclosure are not limited thereto.

Ninth via electrodes VA9 may penetrate the ninth insulating layer INS9 and may be connected to the exposed eighth conductive layers ML8, respectively. The ninth via electrodes VA9 may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or may include an alloy or a compound including any one selected therefrom. In one or more embodiments, a thickness of the ninth via electrode VA9 may be about 16,500 Å.

The display element layer EML may be located on the light emitting element backplane EBP. The display element layer EML may include a plurality of connection electrodes ANC, a plurality of reflective electrodes RL, a planarization layer PNS, a pixel defining layer PDL, a plurality of first electrodes AND, a light emitting stack IL, a second electrode CAT, and a separator SPR.

In addition, the display element layer EML may include a first emission area EA1, a second emission area EA2, and a third emission area EA3. Each of the first emission area EA1, the second emission area EA2, and the third emission area EA3 may be an area where a first electrode AND, the light emitting stack IL, and the second electrode CAT are sequentially stacked (e.g., in the stated order). Each of the first emission area EA1, the second emission area EA2, and the third emission area EA3 may be an area where a light emitting element LE including the first electrode AND, the light emitting stack IL, and the second electrode CAT is located. Each of the first emission area EA1, the second emission area EA2, and the third emission area EA3 may be defined by the pixel defining layer PDL.

The connection electrodes ANC may be located on the ninth insulating layer INS9. For example, the connection electrodes ANC may be located on the ninth insulating layer INS9 such that they are connected to the ninth via electrodes VA9, respectively. In one or more embodiments, the connection electrodes ANC may include titanium nitride (TiN) or a transparent conductive oxide. For example, the transparent conductive oxide may be indium tin oxide (ITO) or indium zinc oxide (IZO), but embodiments of the present disclosure are not limited thereto.

The reflective electrodes RL may be located on the connection electrodes ANC, respectively. Each of the reflective electrodes RL may include (e.g., be formed of) any one selected from among copper (Cu), aluminum (Al), silver (Ag), tungsten (W), molybdenum (Mo), chromium (Cr), gold (Au), titanium (Ti), nickel (Ni), and neodymium (Nd), or may include an alloy a compound including any one selected therefrom. For example, in one or more embodiments, each of the reflective electrodes RL may include aluminum (Al) or silver (Ag). Among the reflective electrode RL and the connection electrode ANC, the connection electrode ANC may have a greater area. For example, in plan view, the area of the connection electrode ANC may be greater than the area of the reflective electrode RL so that the edge of the connection electrode ANC surrounds the reflective electrode RL.

The optical auxiliary layers OAL may be located on the reflective electrodes RL, respectively. For example, the optical auxiliary layers OAL may be located on upper surfaces of the reflective electrodes RL and side surfaces of the reflective electrodes RL. The optical auxiliary layers OAL may be in contact (or in direct contact) with the upper surfaces of the reflective electrodes RL and the sider surfaces of the reflective electrodes RL. In addition, the optical auxiliary layer OAL may be located on an edge of the connection electrode ANC. The optical auxiliary layer OAL may be in contact (or in direct contact) with the edge of an upper surface of the connection electrode ANC. The optical auxiliary layer OAL may surround the upper surface and the side surface of the reflective electrode RL. For example, the optical auxiliary layer OAL may completely surround the reflective electrode RL together with the connection electrode ANC. For example, in a cross-sectional view, the reflective electrode RL may be completely surrounded by the optical auxiliary layer OAL and the connection electrode ANC. In one or more embodiments, the optical auxiliary layer OAL may not cover side surfaces of the connection electrode ANC. The optical auxiliary layer OAL may be formed of a silicon oxide (SiOₓ)-based inorganic layer, but embodiments of the present disclosure are not limited thereto.

Each of light emitting elements LE may include a first electrode AND, the light emitting stack IL, and the second electrode CAT.

The first electrode AND may be located on the optical auxiliary layer OAL. For example, the first electrode AND may be located on an upper surface of the optical auxiliary layer OAL, side surfaces of the optical auxiliary layer OAL, side surfaces of the connection electrode ANC, and an upper surface of the ninth insulating layer INS9. The first electrode AND may be in contact (or in direct contact) with the upper surface of the optical auxiliary layer OAL, the side surfaces of the optical auxiliary layer OAL, the side surfaces of the connection electrode ANC, and the upper surface of the ninth insulating layer INS9. Because side surfaces of the first electrode AND and the side surfaces of the connection electrode ANC contact each other, the first electrode AND and the connection electrode ANC may be electrically connected to each other. The optical auxiliary layer OAL may be located between the first electrode AND and the reflective electrode RL. For example, the optical auxiliary layer OAL may be located between the side surface of the first electrode AND and the side surface of the reflective electrode RL. Accordingly, a direct contact between the first electrode AND and the reflective electrode RL may be prevented.

A thickness of the first electrode AND on the side surfaces of the optical auxiliary layer OAL may be different from a thickness of the first electrode AND on the upper surface of the optical auxiliary layer OAL. For example, the thickness of the first electrode AND on the side surfaces of the optical auxiliary layer OAL may be smaller than the thickness of the first electrode AND on the upper surface of the optical auxiliary layer OAL. For example, the thickness of the first electrode AND overlapping the side surfaces of the reflective electrode RL may be smaller than the thickness of the first electrode AND overlapping the upper surface of the reflective electrode RL.

The optical auxiliary layer OAL of each of the subpixels SP1, SP2, and SP3 may prevent the reflective electrode RL from being damaged by hydrogen fluoride used in a washing process.

In addition, the optical auxiliary layer OAL may also serve as a resonance film to increase extraction efficiency of light by making resonance distances between the respective subpixels SP1, SP2, and SP3 different from each other. In this regard, according to one or more embodiments, the optical auxiliary layers OAL may have different thicknesses for each of the subpixels SP1, SP2, and SP3.

For example, in one or more embodiments, a thickness TT1 of the optical auxiliary layer OAL in the first subpixel SP1, a thickness TT2 of the optical auxiliary layer OAL in the second subpixel SP2, and a thickness TT3 of the optical auxiliary layer OAL in the third subpixel SP3 may be different from one another. For example, the thickness TT2 of the optical auxiliary layer OAL in the second subpixel SP2 may be greater than the thickness TT1 of the optical auxiliary layer OAL in the first subpixel SP1 and smaller than the thickness TT3 of the optical auxiliary layer OAL in the third subpixel SP3.

The thickness TT1 of the optical auxiliary layer OAL in the first subpixel SP1, the thickness TT2 of the optical auxiliary layer OAL in the second subpixel SP2, and the thickness TT3 of the optical auxiliary layer OAL in the third subpixel SP3 may be set in consideration of a main peak wavelength of the first light, a main peak wavelength of the second light, a main peak wavelength of the third light, a distance from a first stack layer of the light emitting stack IL to the reflective electrode RL in the first emission area EA1, a distance from a second stack layer of the light emitting stack IL to the reflective electrode RL in the second emission area EA2, and a distance from a third stack layer of the light emitting stack IL to the reflective electrode RL in the third emission area EA3, and accordingly, a resonance distance of the first light, a resonance distance of the second light, and a resonance distance of the third light may be set.

The first electrode AND of each of the light emitting elements LE may be connected to the drain region DA or the source region SA of a pixel transistor PTR through the connection electrode ANC, the first through ninth via electrodes VA1 through VA9, the first through eighth conductive layers ML1 through ML8, and a contact terminal CTE.

The first electrode AND of each of the light emitting elements LE may include (e.g., be formed of) any one selected from among copper (Cu), aluminum (Al), tungsten (W), molybdenum (Mo), chromium (Cr), gold (Au), titanium (Ti), nickel (Ni), and neodymium (Nd), or may include an alloy or a compound including any one selected therefrom. For example, in one or more embodiments, the first electrode AND of each of the light emitting elements LE may be titanium nitride (TiN).

The pixel defining layer PDL may define the first through third emission areas EA1 through EA3. The pixel defining layer PDL may be located on a partial area of the first electrode AND of each of the light emitting elements LE. The pixel defining layer PDL may cover edges of the first electrode AND of each of the light emitting elements LE. The pixel defining layer PDL may contact (or directly contact) the first electrode AND. The pixel defining layer PDL may be located on the first electrode AND. For example, the pixel defining layer PDL may be located on an upper surface of the first electrode AND and side surface of the first electrode AND. In addition, the pixel defining layer PDL may be located on the ninth insulating layer INS9. The pixel defining layer PDL may be in contact (or in direct contact) with the ninth insulating layer INS9. The pixel defining layer PDL may include a material including a silicon nitride (SiNₓ). In addition, as the pixel defining layer PDL is formed of a different material from the planarization layer PNS, which will be described later, the pixel defining layer PDL may function as an etch stop film that defines a thickness (or height) of the planarization layer PNS when the planarization layer PNS is partially removed by chemical mechanical polishing (CMP).

The first emission area EA1 may be defined as an area in the first subpixel SP1 where a first electrode AND, the light emitting stack IL, and the second electrode CAT are sequentially stacked (e.g., in the stated order) to emit light. The second emission area EA2 may be defined as an area in the second subpixel SP2 where a first electrode AND, the light emitting stack IL, and the second electrode CAT are sequentially stacked (e.g., in the stated order) to emit light. The third emission area EA3 may be defined as an area in the third subpixel SP3 where a first electrode AND, the light emitting stack IL, and the second electrode CAT are sequentially stacked (e.g., in the stated order) to emit light.

The planarization layer PNS may be located between the first electrodes AND of the subpixels in order to remove steps between the subpixels SP1, SP2, and SP3. For example, the planarization layer PNS may be located between the pixel defining layers PDL. The planarization layer PNS may include a material including a silicon oxide (SiOₓ).

The separator SPR may be located on the pixel defining layers PDL and the planarization layer PNS. In plan view, as illustrated in FIG. 5 and FIG. 6, each separator SPR may be shaped like a closed curve around (e.g., surrounding) each of the emission areas EA1 through EA3. Each separator SPR may be located on the pixel defining layer PDL and the planarization layer PNS to surround each of the emission areas EA1 through EA3. The separator SPR may be a structure to cut the light emitting stack IL. To this end, according to one or more embodiments, the separator SPR may include a first bank BK1, a second bank BK2, and a third bank BK3 having different areas.

The first bank BK1 may be located on the pixel defining layer PDL and the planarization layer PNS. The first bank BK1 may be formed of a same material as the planarization layer PNS. For example, in one or more embodiments, the first bank BK1 may include a material including silicon oxide (SiOₓ). In these embodiments, the first bank BK1 and the planarization layer PNS may be integrally formed without an interface.

The second bank BK2 may be located on the first bank BK1. The second bank BK2 may be located on the first bank BK1 to overlap the first bank BK1. In this regard, the area of the second bank BK2 may be smaller than the area of the first bank BK1. For example, in plan view, the area of the second bank BK2 may be smaller than the area of the first bank BK1 so that the second bank BK2 is surrounded by the edge of the first bank BK1. An etch rate of the second bank BK2 may be different from an etch rate of the first bank BK1. For example, the etch rate of the second bank BK2 may be higher than the etch rate of the first bank BK1. In one or more embodiments, the second bank BK2 may include a material including silicon nitride (SiNₓ). In one or more embodiments, the second bank BK2 may include a material including a metal. For example, the second bank BK2 may include a material including at least one of titanium (Ti), tantalum (Ta), or molybdenum (Mo).

The third bank BK3 may be located on the second bank BK2. The third bank BK3 may be located on the second bank BK2 to overlap the second bank BK2. In one or more embodiments, the area of the third bank BK3 may be greater than the area of the second bank BK2. For example, in plan view, the area of the third bank BK3 may be greater than the area of the second bank BK2 so that the third bank BK3 surrounds the edge of the second bank BK2, for example, extending beyond the edge of the second bank BK2. Accordingly, as illustrated in FIG. 9, the third bank BK3 may include a tip TP not overlapping the second bank BK2, for example, overhanging the second bank BK2. An etch rate of the second bank BK2 may be different from an etch rate of the third bank BK3. For example, the etch rate of the second bank BK2 may be higher than the etch rate of the third bank BK3. The third bank BK3 may include a material including silicon oxide (SiOₓ).

In cross-section, the separator SPR including the first bank BK1, the second bank BK2, and the third bank BK3 may be smaller at the central portion than at the top and bottom, forming an undercut below the third bank BK3.

The light emitting stack IL may be located on the first electrodes AND, the pixel defining layers PDL, and the separators SPR. For example, in one or more embodiments, the light emitting stack IL may be located on the first bank BK1 and the third bank BK3 of the separator SPR. The light emitting stack IL may be cut on the separator SPR. For example, the light emitting stack IL may be cut between the first bank BK1 and the third bank BK3. In plan view, the light emitting stack IL may be cut along the separator SPR. Therefore, the light emitting stack IL may be divided into a portion in contact with the first electrode AND in each emission area and a portion located on an area excluding the emission area (e.g., on the third bank BK3 of the separator SPR). For example, the light emitting stack IL may be cut along the separator SPR so that it is separated for each subpixel. Accordingly, lateral leakage current between adjacent subpixels SP1 through SP3 may be minimized or reduced. As the lateral leakage current is minimized or reduced, a color mixing phenomenon between the adjacent subpixels SP1 through SP3 may be prevented or reduced, thereby improving the image quality of the display device 10.

The light emitting stack IL may include a plurality of stack layers stacked sequentially along the third direction DR3. For example, in one or more embodiments, the light emitting stack IL may have a three-tandem structure including a first stack layer, a second stack layer on the first stack layer, and a third stack layer on the second stack layer. Here, the second stack layer may be located between the first stack layer and the third stack layer. However, embodiments of the present disclosure are not limited thereto. For example, in one or more embodiments, the light emitting stack IL may have a two-tandem structure including two stack layers.

In the three-tandem structure, the first stack layer, the second stack layer, and the third stack layer of the light emitting stack IL may provide light of different colors (or wavelengths). For example, in one or more embodiments, any one selected from among the first stack layer, the second stack layer, and the third stack layer may provide light of a first color (e.g., green), another stack layer may provide light of a second color (e.g., red), and the other stack layer may provide light of a third color (e.g., blue).

The first stack layer of the light emitting stack IL may have a structure in which a first hole transport layer, a first organic light emitting layer, and a first electron transport layer are sequentially stacked (e.g., in the stated order). The second stack layer of the light emitting stack IL may have a structure in which a second hole transport layer, a second organic light emitting layer, and a second electron transport layer are sequentially stacked (e.g., in the stated order). The third stack layer of the light emitting stack IL may have a structure in which a third hole transport layer, a third organic light emitting layer, and a third electron transport layer are sequentially stacked (e.g., in the stated order). Here, the first organic light emitting layer, the second organic light emitting layer, and the third organic light emitting layer may provide light of different colors (or wavelengths). For example, in one or more embodiments, any one selected from among the first organic light emitting layer, the second organic light emitting layer, and the third organic light emitting layer may provide light of the first color (e.g., green), another organic light emitting layer may provide light of the second color (e.g., red), and the other organic light emitting layer may provide light of the third color (e.g., blue).

A first charge generation layer may be located between the first stack layer and the second stack layer to supply charges (e.g., holes) to the second stack layer and electrons to the first stack layer. The first charge generation layer may include an n-type (kind) charge generation layer that supplies electrons to the first stack layer and a p-type (kind) charge generation layer that supplies holes to the second stack layer. The n-type (kind) charge generation layer may include a dopant of a metallic material.

A second charge generation layer may be located between the second stack layer and the third stack layer to supply charges (e.g., holes) to the third stack layer and electrons to the second stack layer. The second charge generation layer may include an n-type (kind) charge generation layer that supplies electrons to the second stack layer and a p-type (kind) charge generation layer that supplies holes to the third stack layer.

The first stack layer of the light emitting stack IL may be located on the first electrodes AND, the pixel defining layers PDL, and the separators SPR. Due to the separator SPR described above, the first stack layer of the light emitting stack IL may be broken between neighboring subpixels SP1 through SP3. The second stack layer of the light emitting stack IL may be located on the first stack layer. Due to the separator SPR described above, the second stack layer IL2 may be broken between the neighboring subpixels SP1 through SP3. The third stack layer of the light emitting stack IL may be located on the second stack layer. The third stack layer of the light emitting stack IL may not be broken by the separator SPR and may cover the second stack layer.

In the three-tandem structure, the separator SPR may be a structure for breaking the first charge generation layer and the second charge generation layer of the display element layer EML between neighboring subpixels SP1 through SP3. In addition, in the two-tandem structure, the separator SPR may be a structure for breaking a charge generation layer located between a lower stack layer and an upper stack layer.

The second electrode CAT may be located on the light emitting stack IL. For example, in one or more embodiments, the second electrode CAT may be located on the third stack layer of the light emitting stack IL. The second electrode CAT may be located on the third stack layer of the light emitting stack IL without being broken by the separator SPR. The second electrode CAT may include a semi-transmissive conductive material such as magnesium (Mg), silver (Ag), or an alloy of Mg and Ag. In this regard, the light output efficiency of each of the first through third subpixels SP1 through SP3 may be increased by a microcavity.

The encapsulation layer TFE may be located on the display element layer EML. The encapsulation layer TFE may include one or more inorganic films TFE1 and TFE3 to prevent or reduce the penetration of oxygen and/or moisture into the display element layer EML. For example, in one or more embodiments, the encapsulation layer TFE may include a first encapsulating inorganic film TFE1, an encapsulating organic film TFE2, and a second encapsulating inorganic film TFE3.

The first encapsulating inorganic film TFE1 may be located on the second electrode CAT. The first encapsulating inorganic film TFE1 may be a multilayer in which one or more inorganic films selected from among silicon nitride (SiNₓ), silicon oxynitride (SiON), and silicon oxide (SiOₓ) are alternately stacked. The first encapsulating inorganic film TFE1 may be formed by a chemical vapor deposition (CVD) process.

In one or more embodiments, the encapsulating organic film TFE2 may be a monomer. In one or more embodiments, the encapsulating organic film TFE2 may be an organic film such as formed of an acryl resin, an epoxy resin, a phenolic resin, a polyamide resin, or a polyimide resin.

The second encapsulating inorganic film TFE3 may be located on the encapsulating organic film TFE2. The second encapsulating inorganic film TFE3 may be a multilayer in which one or more inorganic films selected from among silicon nitride (SiNₓ), silicon oxynitride (SiON), and silicon oxide (SiOₓ) are alternately stacked. The second encapsulating inorganic film TFE3 may be formed by a chemical vapor deposition (CVD) process.

An organic film APL may be a layer for increasing the interfacial adhesion between the encapsulation layer TFE and the optical layer OPL. The organic film APL may be an organic layer such as formed of an acryl resin, an epoxy resin, a phenolic resin, a polyamide resin, or a polyimide resin.

The optical layer OPL includes a plurality of color filters CF1 through CF3, a plurality of lenses LNS, and a filling layer FIL. The color filters CF1 through CF3 may include first through third color filters CF1 through CF3. The first through third color filters CF1 through CF3 may be located on the organic layer APL.

The first color filter CF1 may overlap the first emission area EA1 of the first subpixel SP1. In one or more embodiments, the first color filter CF1 may be to transmit light of the first color (e.g., light in the green wavelength band). Therefore, the first color filter CF1 may be to transmit the light of the first color among the light emitted from the light emitting stack IL of the first emission area EA1.

The second color filter CF2 may overlap the second emission area EA2 of the second subpixel SP2. In one or more embodiments, the second color filter CF2 may be to transmit light of the second color (e.g., light in the red wavelength band). Therefore, the second color filter CF2 may be to transmit the light of the second color among the light emitted from the light emitting stack IL of the second emission area EA2.

The third color filter CF3 may overlap the third emission area EA3 of the third subpixel SP3. The third color filter CF3 may be to transmit light of the third color (e.g., light in the blue wavelength band). Therefore, the third color filter CF3 may be to transmit the light of the third color among the light emitted from the light emitting stack IL of the third emission area EA3.

The lenses LNS may be located on the first color filter CF1, the second color filter CF2, and the third color filter CF3, respectively. Each of the lenses LNS may be a structure for increasing the proportion of light directed to the front of the display device 10. In one or more embodiments, each of the lenses LNS may have an upwardly convex cross-sectional shape, but embodiments of the present specification are not limited thereto.

The filling layer FIL may be located on the lenses LNS. The filling layer FIL may have a set or predetermined refractive index so that light may travel in the third direction DR3 at an interface between the lenses LNS and the filling layer FIL. In addition, the filling layer FIL may be a planarization layer. The filling layer FIL may be an organic layer such as formed of an acryl resin, an epoxy resin, a phenolic resin, a polyamide resin, or a polyimide resin.

The cover layer CVL may be located on the filling layer FIL. The cover layer CVL may be a glass substrate or a polymer resin such as a resin. In one or more embodiments, when the cover layer CVL is a glass substrate, it may be attached onto the filling layer FIL. In these embodiments, the filling layer FIL may serve to bond the cover layer CVL. When the cover layer CVL is a glass substrate, it may serve as an encapsulation substrate. In one or more embodiments, when the cover layer CVL is a polymer resin such as a resin, it may be directly applied on the filling layer FIL.

The polarizing plate POL may be located on a surface of the cover layer CVL. The polarizing plate POL may be a structure for preventing or reducing visibility reduction/degradation due to the reflection of external light. The polarizing plate POL may include a linear polarizing plate and a phase retardation film. For example, in one or more embodiments, the phase retardation film may be a quarter-wave plate (λ/4 plate), but embodiments of the present disclosure are not limited thereto. If visibility reduction/degradation due to the reflection of external light is sufficiently improved by the first through third color filters CF1 through CF3, the polarizing plate POL may not be provided.

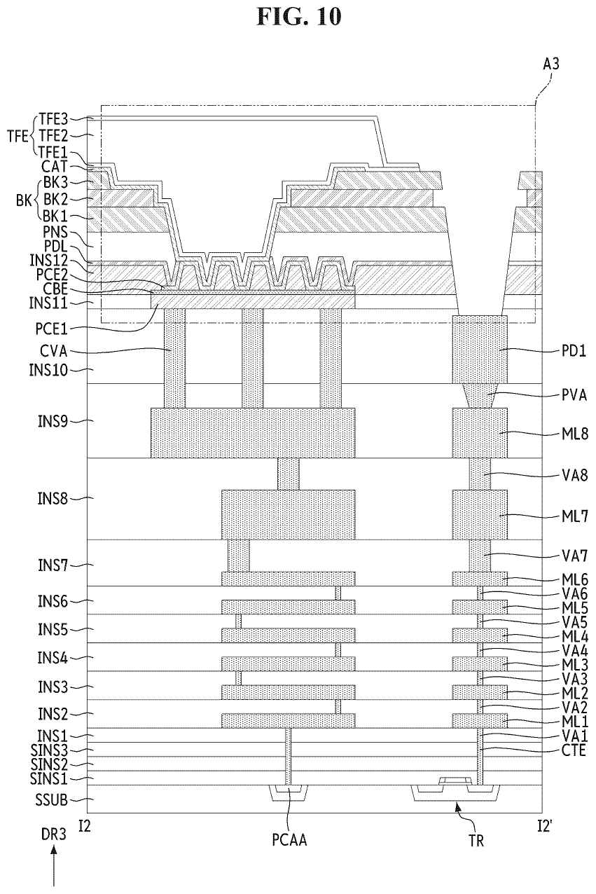

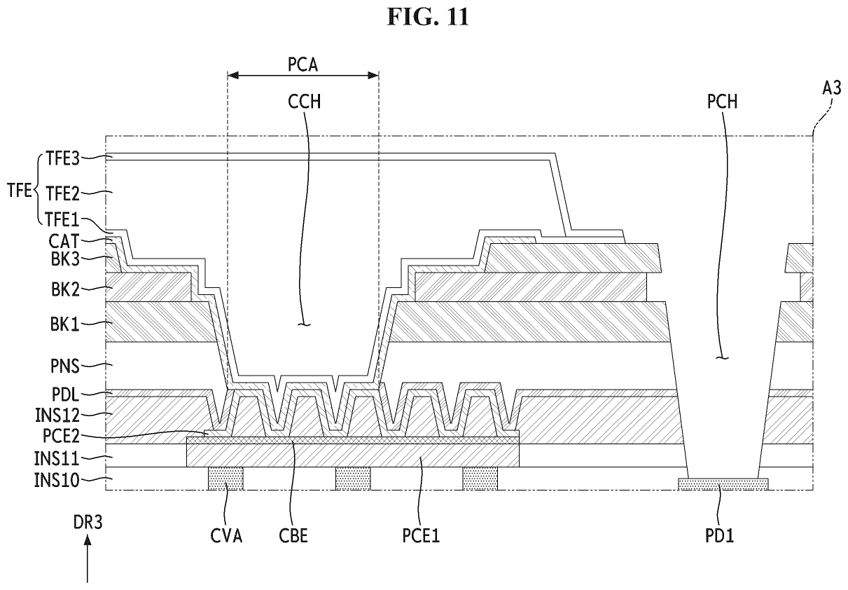

FIG. 10 is a cross-sectional view of an example of the display panel taken along the line I2-I2′ of FIG. 4 according to one or more embodiments of the present disclosure, and FIG. 11 is a detailed cross-sectional view of area A3 of FIG. 10 according to one or more embodiments.

In FIG. 10 and FIG. 11, a power connector PCA and a first pad PD1 located in the non-display area NDA are illustrated.

The power connector PCA may include a first power connection area PCAA of the semiconductor substrate SSUB, a first power connection electrode PCE1, and a second power connection electrode PCE2.

A first driving voltage VSS may be applied to the first power connection area PCAA of the semiconductor substrate SSUB.

The first power connection electrode PCE1 may be located in a hole of an eleventh insulating layer INS11 on a tenth insulating layer INS10. The first power connection electrode PCE1 may be connected to the first power connection area PCAA of the semiconductor substrate SSUB through the first through eighth conductive layers ML1 through ML8, the first through eighth via electrodes VA1 through VA8, and a power via electrode CVA. The first power connection electrode PCE1 may be formed of a same material as the reflective electrode RL.

A power buffer electrode CBE may be located on the first power connection electrode PCE1. In one or more embodiments, the power buffer electrode CBE may include a material including titanium nitride (TiN). In one or more embodiments, the power buffer electrode CBE has a thickness equal to or smaller than about 10 Å.

A twelfth insulating layer INS12 may be located on the power buffer electrode CBE. The twelfth insulating layer INS12 may be formed of a same material as the above-described optical auxiliary layer OAL.

The second power connection electrode PCE2 may be located on the twelfth insulating layer INS12. The second power connection electrode PCE2 may be connected to the power buffer electrode CBE through a plurality of contact holes penetrating the twelfth insulating layer INS12. For example, the second power connection electrode PCE2 may be connected to the first power connection electrode PCE1 through the power buffer electrode CBE. The second power connection electrode PCE2 may include substantially the same material as the first electrode AND.

The second electrode CAT may be connected to the second power connection electrode PCE2 through a power contact hole CCH penetrating the third bank BK3, the second bank BK2, the first bank BK1, the planarization layer PNS, and the pixel defining layer PDL.

In addition, the tenth insulating layer INS10 may be located between the ninth insulating layer INS9 and the eleventh insulating layer INS11. A tenth via electrode may be located in the tenth insulating layer INS10.

The first pad PD1 may be located on the ninth insulating layer INS9. The first pad PD1 may be connected to the transistor TR on the semiconductor substrate SSUB thorough the first through eighth conductive layers ML1 through ML8, the first through eighth via electrodes VA1 through VA8, and a pad via electrode PVA. The first pad PD1 may be formed of a same material as the reflective electrode RL. For example, in one or more embodiments, the first pad PD1 may include a material including aluminum (Al). A thickness of the first pad PD1 may be about 12,000 Å.

The first pad PD1 may be exposed to the outside through a pad contact hole PCH penetrating the third bank BK3, the second bank BK2, the first bank BK1, the planarization layer PNS, the pixel defining layer PDL, the twelfth insulating layer INS12, the eleventh insulating layer INS11, and the tenth insulating layer INS10. The first pad PD1 may be electrically connected to a pad or a bump of the circuit board 300 through the pad contact hole PCH.

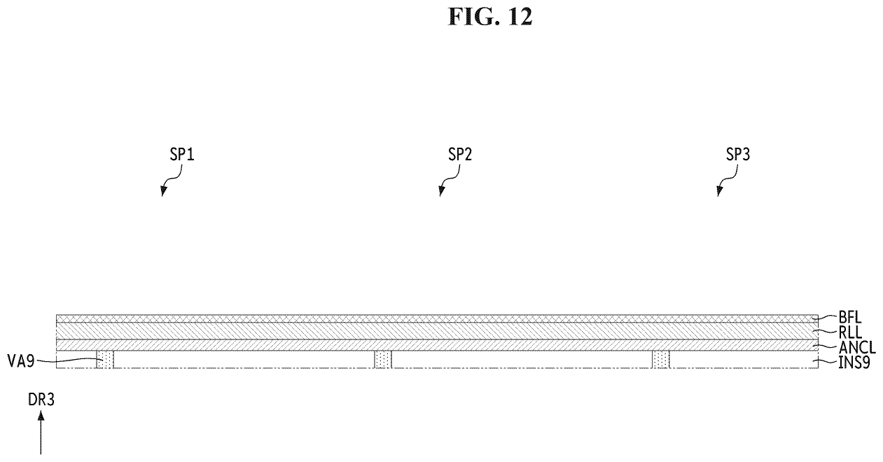

FIGS. 12, 13, 14, 15, 16, 17, 18, 19, 20, 21, 22, 23, 24, 25, 26, 27, and 28 are process cross-sectional views illustrating a method of fabricating a display device according to one or more embodiments of the present disclosure. For example, FIGS. 12 through 28 may be process cross-sectional views illustrating a method of fabricating the display device of FIG. 8 according to one or more embodiments.

First, referring to FIGS. 7 through 12, as illustrated in FIG. 12, the ninth insulating layer INS9 may be formed on the semiconductor substrate SSUB, and ninth via electrodes VA9 may be formed in via holes of the ninth insulating layer INS9. Then, a connection electrode layer ANCL may be formed on the ninth insulating layer INS9 to contact the ninth via electrodes VA9. For example, the connection electrode layer ANCL may be formed on the entire surface of the semiconductor substrate SSUB including the ninth insulating layer INS9 and the ninth via electrodes VA9 to cover the ninth insulating layer INS9 and the ninth via electrodes VA9. Next, a reflective electrode layer RLL may be formed on the entire surface of the semiconductor substrate SSUB including the connection electrode layer ANCL, and then, a buffer layer BFL may be formed on the entire surface of the semiconductor substrate SSUB including the connection electrode layer ANCL. At this time, the connection electrode layer ANCL, the reflective electrode layer RLL, and the buffer layer BFL may also be formed on the first power connection area PCAA (see FIG. 10).

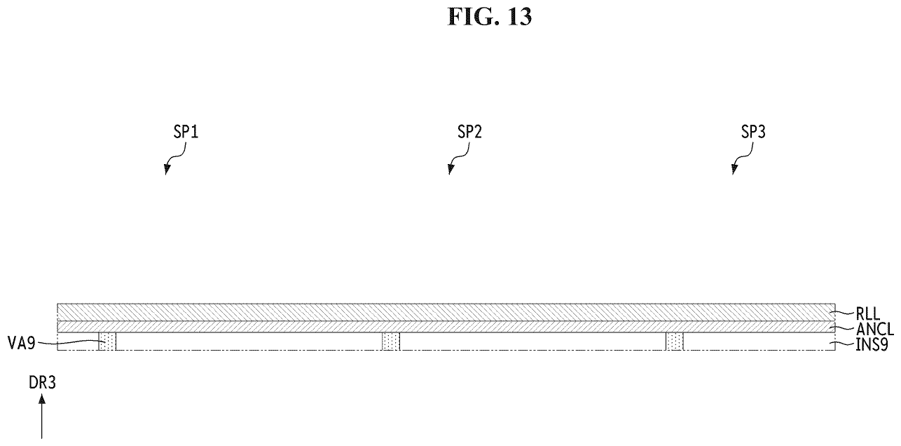

Subsequently, as illustrated in FIG. 13, the power buffer electrode CBE may be formed on the first power connection area PCAA as the buffer layer BFL is patterned. For example, the buffer layer BFL on the reflective electrode layer RLL may be removed.

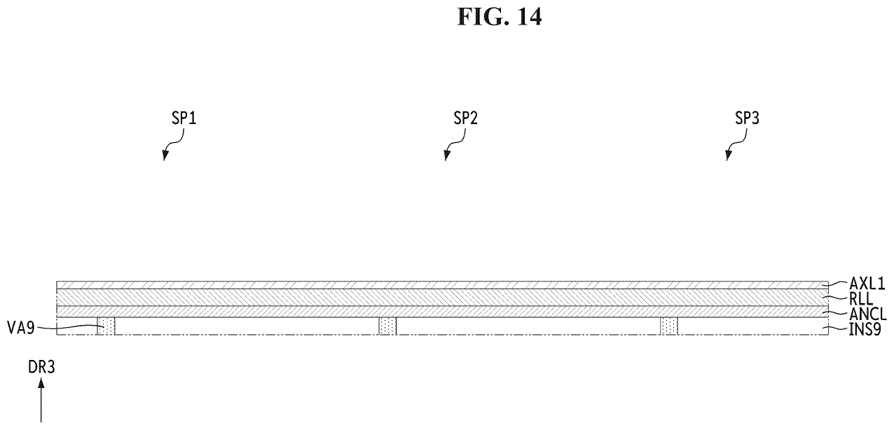

Next, as illustrated in FIG. 14, a first auxiliary layer AXL1 may be formed on the entire surface of the semiconductor substrate SSUB including the reflective electrode layer RLL. Here, the first auxiliary layer AXL1 may be, for example, deposited on the entire surface of the semiconductor substrate SSUB using an atomic layer deposition (ALD) method.

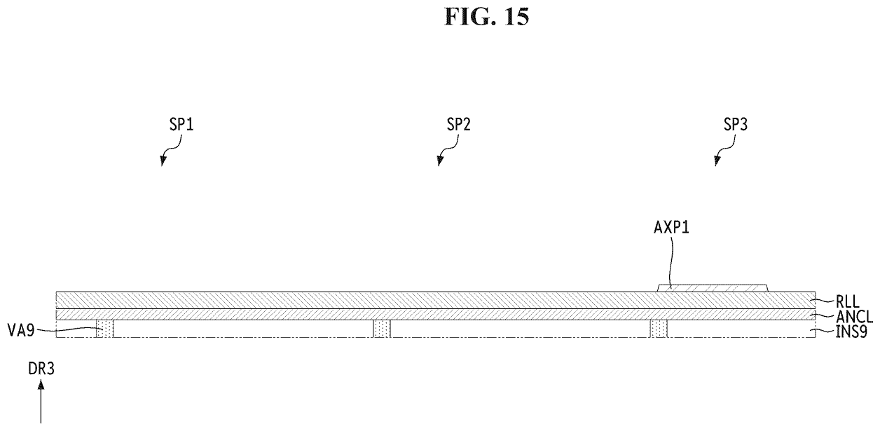

Subsequently, as illustrated in FIG. 15, a first auxiliary pattern AXP1 may be formed on the reflective electrode layer RLL of the third subpixel SP3. For example, the first auxiliary pattern AXP1 may be formed on the reflective electrode layer RLL of the third subpixel SP3 as the first auxiliary layer AXL1 is patterned through a photolithography process.

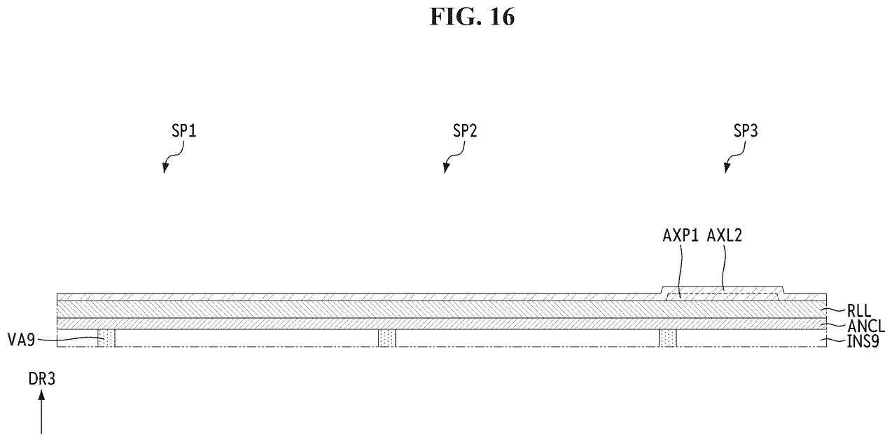

Next, as illustrated in FIG. 16, a second auxiliary layer AXL2 may be formed on the entire surface of the semiconductor substrate SSUB including the first auxiliary pattern AXP1 and the reflective electrode layer RLL. Here, the second auxiliary layer AXL2 may be, for example, deposited on the entire surface of the semiconductor substrate SSUB using the atomic layer deposition (ALD) method.

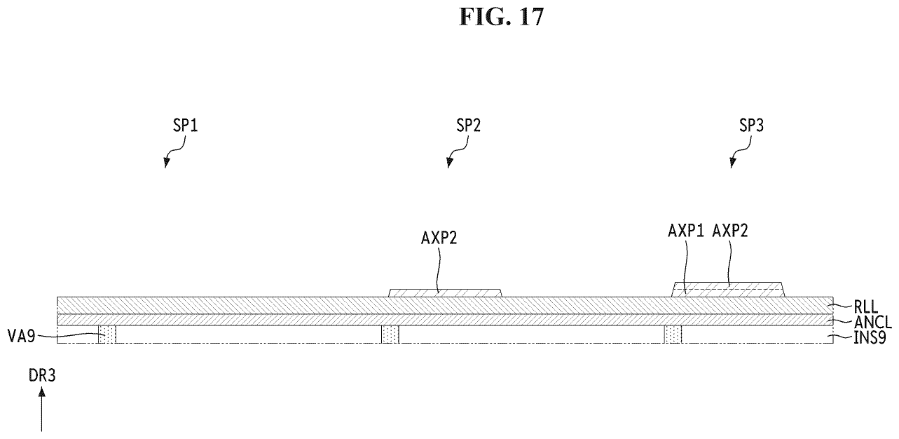

Subsequently, as illustrated in FIG. 17, a second auxiliary pattern AXP2 may be formed on the reflective electrode layer RLL of the second subpixel SP2 and the first auxiliary pattern AXP1 of the third subpixel SP3. For example, the second auxiliary pattern AXP2 may be formed on each of the reflective electrode layer RLL of the second subpixel SP2 and the first auxiliary pattern AXP1 of the third subpixel SP3 as the second auxiliary layer AXL2 is patterned through a photolithography process.

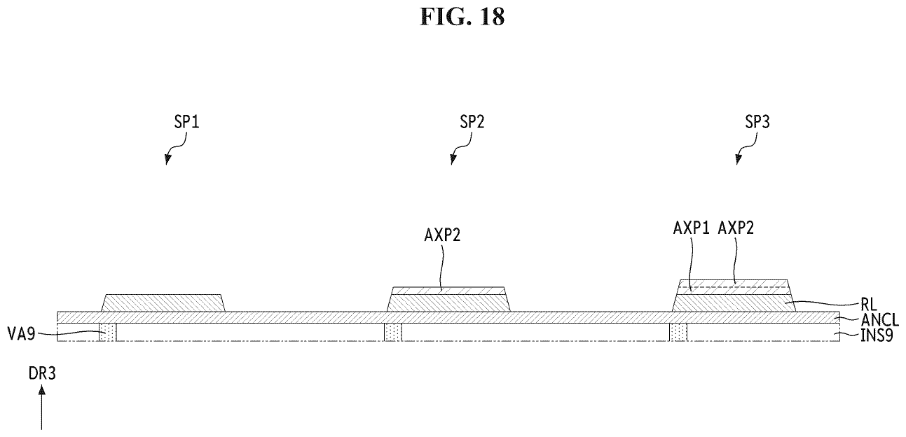

Subsequently, as illustrated in FIG. 18, a reflective electrode RL may be formed in each of the first subpixel SP1, the second subpixel SP2, and the third subpixel SP3 as the reflective electrode layer RLL is patterned through a photolithography process. For example, the reflective electrode RL of the first subpixel SP1 may be formed on the connection electrode layer ANCL of the first subpixel SP1, the reflective electrode RL of the second subpixel SP2 may be formed between the second auxiliary pattern AXP2 and the connection electrode layer ANCL of the second subpixel SP2, and the reflective electrode RL of the third subpixel SP3 may be formed between the first auxiliary pattern AXP1 and the connection electrode layer ANCL of the third subpixel SP.

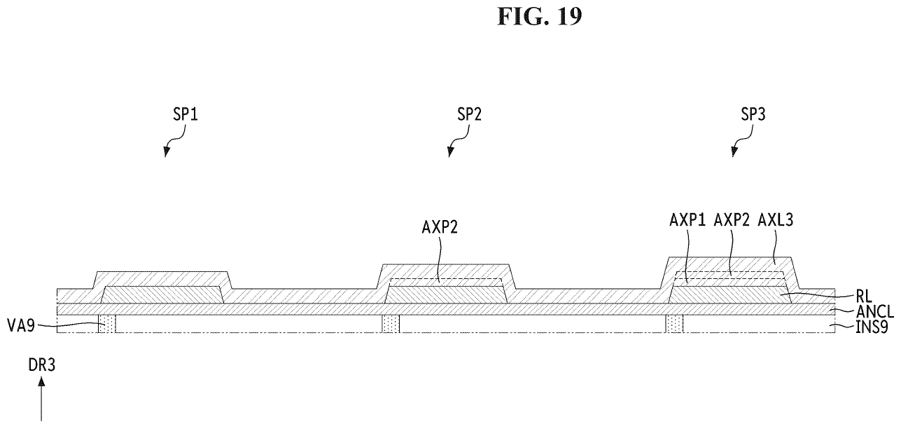

Next, as illustrated in FIG. 19, a third auxiliary layer AXL3 may be formed on the entire surface of the semiconductor substrate SSUB including the reflective electrodes RL and the second auxiliary patterns AXP2. Here, the third auxiliary layer AXL3 may be, for example, deposited on the entire surface of the semiconductor substrate SSUB through the atomic layer deposition (ALD) method.

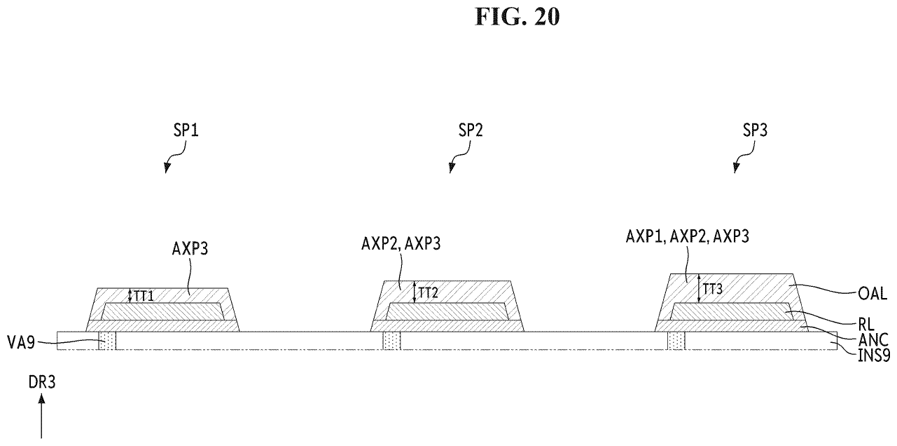

Next, as the third auxiliary layer AXL3 and the connection electrode layer ANCL are patterned together through a photolithography process, in addition to forming the connection electrode ANC of the first subpixel SP1, the connection electrode ANC of the second subpixel SP2, and the connection electrode ANC of the third subpixel SP3 as illustrated in FIG. 20, optical auxiliary layers OAL having different thicknesses may be formed on the reflective electrode RL of the first subpixel SP1, the reflective electrode RL of the second subpixel SP2, and reflective electrode RL of the third subpixel SP3, respectively. For example, the optical auxiliary layer OAL of the first subpixel SP1 may include the third auxiliary pattern AXP3, the optical auxiliary layer OAL of the second subpixel SP2 may include the second auxiliary pattern AXP2 and the third auxiliary pattern AXP3, and the optical auxiliary layer OAL of the third subpixel SP3 may include the first auxiliary pattern AXP1, the second auxiliary pattern AXP2, and the third auxiliary pattern AXP3. Each optical auxiliary layer OAL may be formed on the upper surface of the reflective electrode RL and the side surfaces of the reflective electrode RL. In addition, the edge of each optical auxiliary layer OAL may be formed on the edge of the upper surface of each connection electrode ANC.

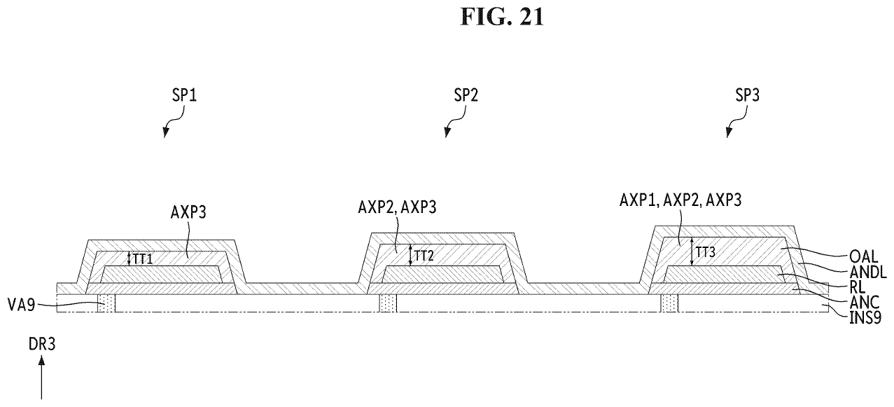

Next, as illustrated in FIG. 21, a first electrode layer ANDL may be formed on the optical auxiliary layers OAL and the ninth insulating layer INS9. In one or more embodiments, a washing process may be performed after each forming process of the first auxiliary pattern AXP1, the second auxiliary pattern AXP2, and the third auxiliary pattern AXP3. In this regard, the washing process in an electrostatic chuck (ESC) method may be performed to prevent or reduce damage of the exposed reflective electrode layer RLL and the reflective electrode RL.

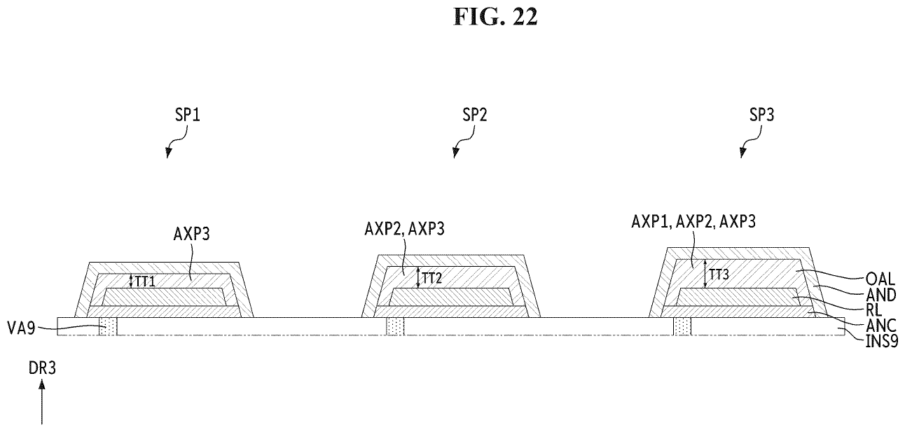

Thereafter, as illustrated in FIG. 22, a first electrode AND may be formed for each of the subpixels SP1, SP2, and SP3 as the first electrode layer ANDL is patterned through a photolithography process.

Subsequently, a washing process may be performed. For example, after a dry etching process used during the photolithography process, a polymer may remain as a reaction by-product on the sidewall of a patterned metal, and a washing process to remove such polymers may be performed using a stripper containing solvent. Here, hydrogen fluoride (e.g., diluted HF) may be used as a stripper.

If (e.g., when) the first electrode AND is made of a material containing ITO, the silver (Ag) component of the reflective electrode RL may protrude onto the first electrode AND through a pin hole of the first electrode AND. For example, a portion of the reflective electrode RL may swell due to heat during a curing process (e.g., a heat treatment process) to alleviate defects that may occur in subsequent processes, and a portion of the swollen reflective electrode RL may be exposed to the outside through the pin hole in the first electrode AND. As a result, the portion of the swollen reflective electrode RL exposed to the outside through the pin hole may be exposed to hydrogen fluoride that is used in the above-described washing process (e.g., washing process performed after forming the first electrode AND). Then, the hydrogen fluoride may permeate into the reflective electrode RL using the exposed portion of the reflective electrode RL as a permeation path. In this manner, the reflective electrode RL may be damaged. If (e.g., when) the reflective electrode RL is damaged by exposure to hydrogen fluoride, at least a portion of the reflective electrode RL may be lost. As a result, light efficiency may be reduced in an emission area where the reflective electrode RL is lost, and the image of the display device 10 may deteriorate.

However, according to one or more embodiments of the present disclosure, because the optical auxiliary layer OAL is located between the reflective electrode RL and the first electrode AND, a portion of the swollen reflective electrode RL may not pass through the pin hole of the first electrode AND. Accordingly, hydrogen fluoride used during the washing process after forming the first electrode AND may not permeate into the reflective electrode RL. Therefore, according to one or more embodiments, damage of the reflective electrode RL may be prevented by the optical auxiliary layer OAL, even during the washing process.

In one or more embodiments, in order to prevent damage of the reflective electrode RL, a washing process of the above-described electrostatic chuck method may be utilized. However, after forming the first electrode AND, if (e.g., when) the washing process with respect to the semiconductor substrate SSUB is performed through the electrostatic chuck method, the first electrode AND may be damaged (e.g., damage due to corrosion) by a galvanic reaction. Accordingly, it is desirable that the washing process performed after forming the first electrode AND to be performed using a stripper such as hydrogen fluoride. In this regard, because the above-described hydrogen fluoride is blocked by the optical auxiliary layer OAL, damage of the reflective electrode RL may be prevented or reduced as well.

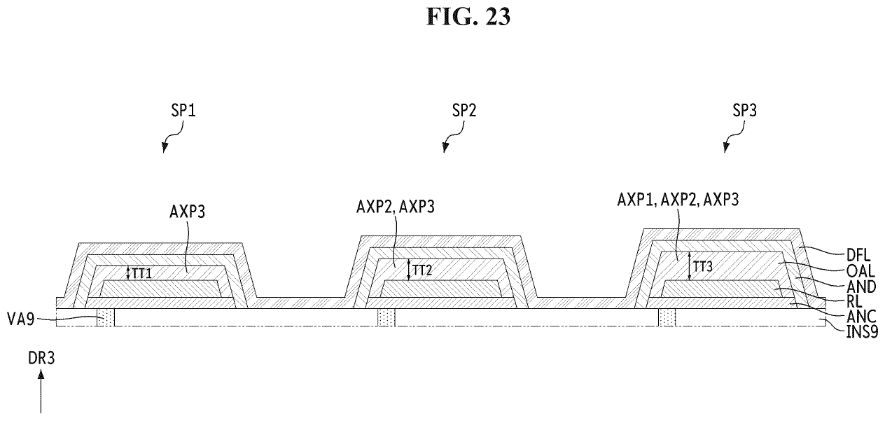

Next, as illustrated in FIG. 23, a defining layer DFL may be formed on the first electrodes AND and the ninth insulating layer INS9.

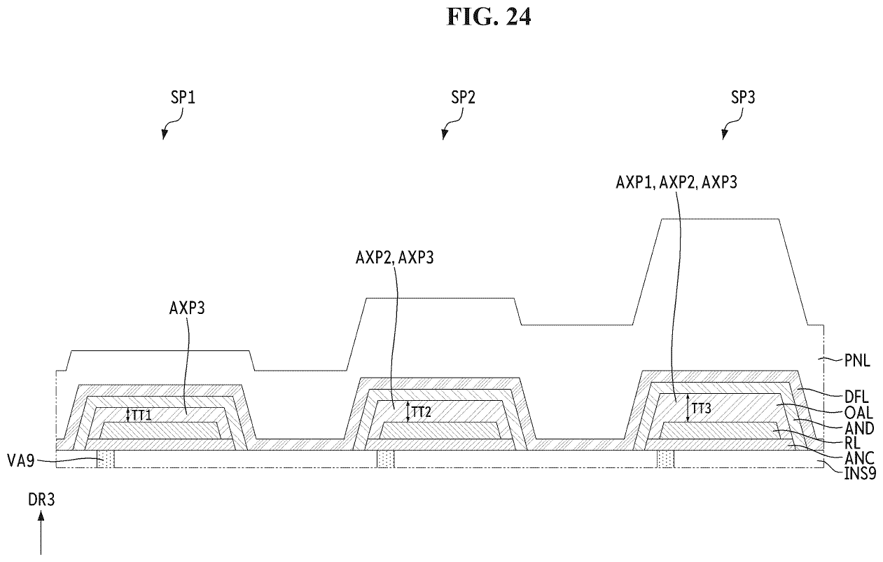

Subsequently, as illustrated in FIG. 24, an intermediate layer PNL may be formed on the defining layer DFL.

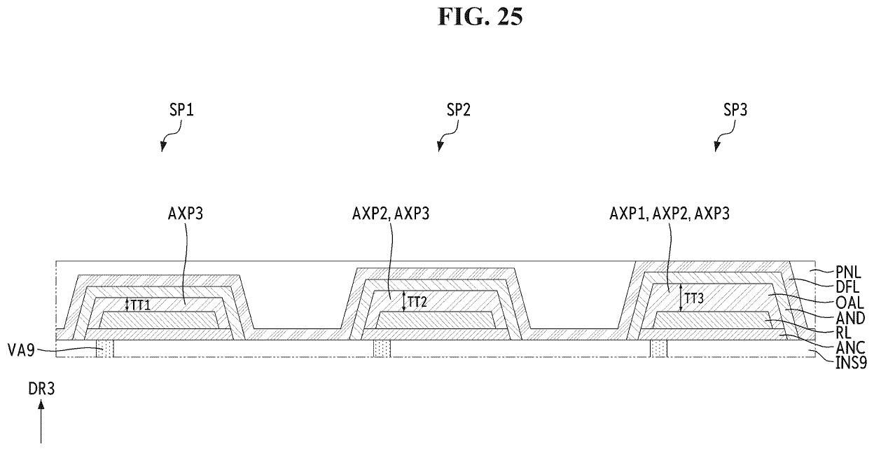

Thereafter, as illustrated in FIG. 25, the intermediate layer PNL may be planarized as the intermediate layer PNL is partially removed through a chemical mechanical polishing process. The upper surface of the intermediate layer PNL may be located at substantially the same height as the highest portion of the defining layer DFL. For example, the upper surface of the intermediate layer PNL may be located at substantially the same height as the highest portion of the defining layer DFL of the third subpixel SP3.

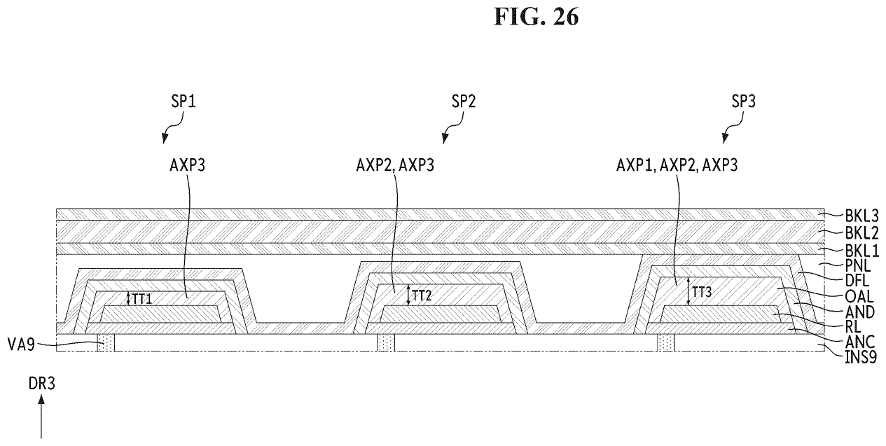

Next, as illustrated in FIG. 26, a first bank layer BKL1 may be formed on the entire surface of the semiconductor substrate SSUB including the intermediate layer PNL and the exposed defining layer DFL (e.g., defining layer DFL of the third subpixel SP3), a second bank layer BKL2 may be formed on the entire surface of the semiconductor substrate SSUB including the first bank layer BKL1, and a third bank layer BKL3 may be formed on the entire surface of the semiconductor substrate SSUB including the second bank layer BKL2.

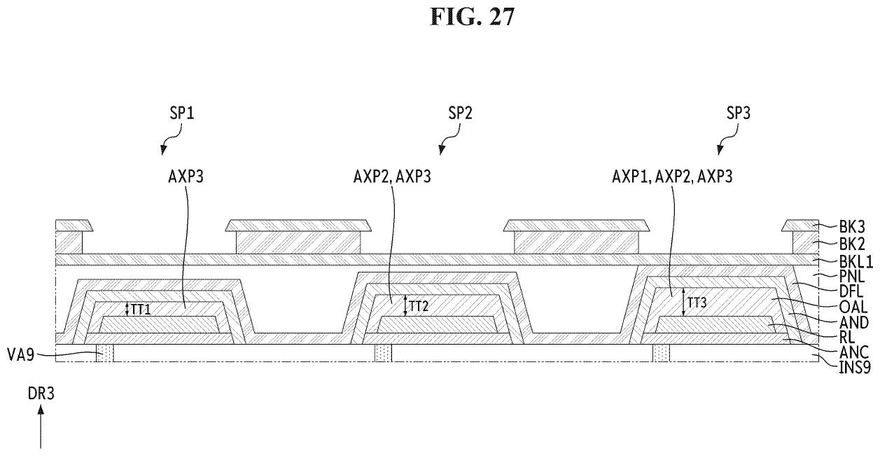

Thereafter, as illustrated in FIG. 27, a second bank BK2 and a third bank BK3 having a reverse tapered shape may be formed as the third bank layer BKL3 and the second bank layer BKL2 are patterned through a photolithography process.

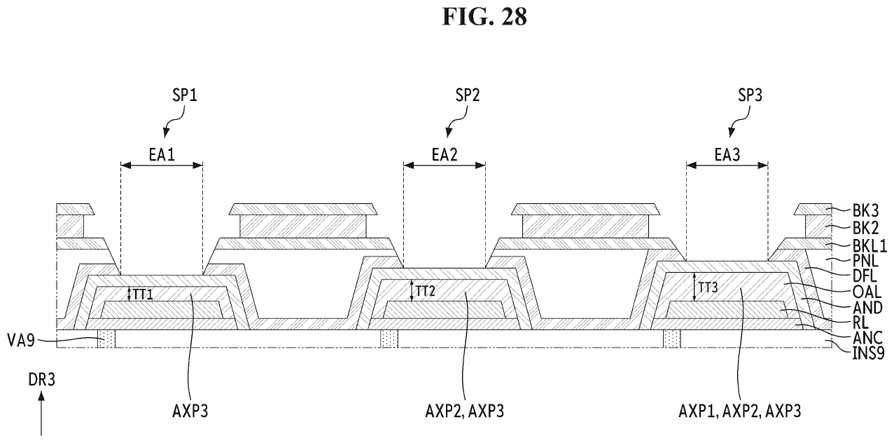

Next, as illustrated in FIG. 28, the first bank layer BKL1, defining layer DFL, and the intermediate layer PNL may be patterned by a photolithography process to form a first bank BK1 and a pixel defining layer PDL and expose the first electrodes AND of first to third subpixels SP1, SP2, and SP3. For example, the pixel defining layer PDL may include a first emission area EA1 exposing the first electrode AND of the first subpixel SP1, a second emission area EA2 exposing the first electrode AND of the second subpixel SP2, and a third emission area EA3 exposing the first electrode AND of the third subpixel SP3.

Next, as illustrated in FIG. 8, a light emitting stack IL may be formed on the first electrodes AND, the pixel defining layer PDL, the planarization layer PNS (corresponding to the patterned intermediate layer PNL illustrated in FIG. 28), and the separators SPR; a second electrode CAT may be formed on the light emitting stack IL; and an encapsulation layer TFE may be formed on the second electrode CAT. Here, the light emitting stack IL may be separated for each of the subpixels SP1, SP2, and SP3 by the separator SPR.

In one or more embodiments, through the processes illustrated in FIGS. 14 to 23, a first power connection electrode PCE1, a twelfth insulating layer INS12, and a second power connection electrode PCE2 may be formed in the first power connection area PCAA located in the non-display area NDA of the display panel 100 (see FIG. 4). The first power connection electrode PCE1 may be formed of the same material as the above-described reflective electrode RL; the twelfth insulating layer INS12 may be formed of the same material as the first auxiliary pattern AXP1, the second auxiliary pattern AXP2, and the third auxiliary pattern AXP3 described above; and the second power connection electrode PCE2 may be formed of the same material as the first electrode AND described above.

The display device 10 according to one or more embodiments may be applied to one or more suitable electronic devices. An electronic device according to one or more embodiments may include the above-described display device 10 and may further include modules or devices having other additional functions, in addition to the display device 10.

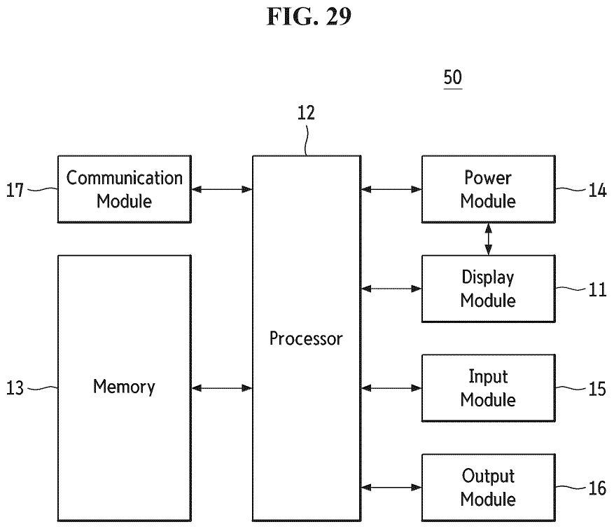

FIG. 29 is a block diagram of an electronic device according to one or more embodiments of the present disclosure. Referring to FIG. 29, an electronic device 50 according to one or more embodiments may include a display module 11, a processor 12, a memory 13, and a power module 14. The electronic device 50 may further include an input module 15, a non-image output module 16, and/or a communication module 17.

The electronic device 50 may output various information in the form of images through the display module 11. When the processor 12 executes an application stored in the memory 13, image information provided by the application may be provided to a user through the display module 11. The power module 14 may include a power supply module such as a power adapter or a battery device and a power conversion module which generates power necessary for the operation of the electronic device 50 by converting power supplied by the power supply module. The input module 15 may provide input information to the processor 12 and/or the display module 11. The non-image output module 16 may receive non-image information, such as sound, haptic, and light, from the processor 12 and provide the information to a user. The communication module 17 is a module that is responsible for transmitting and receiving information between the electronic device 50 and an external device and may include a receiving unit and a transmitting unit.

At least one of the elements of the electronic device 50 described above may be included in a display device according to one or more embodiments described above. In one or more embodiments, some of individual modules functionally included in one module may be included in the display device, and other modules may be provided separately from the display device. For example, in one or more embodiments, the display device may include the display module 11, and the processor 12, the memory 13, and the power module 14 may be provided not in the display device but in the form of other devices within the electronic device 50.

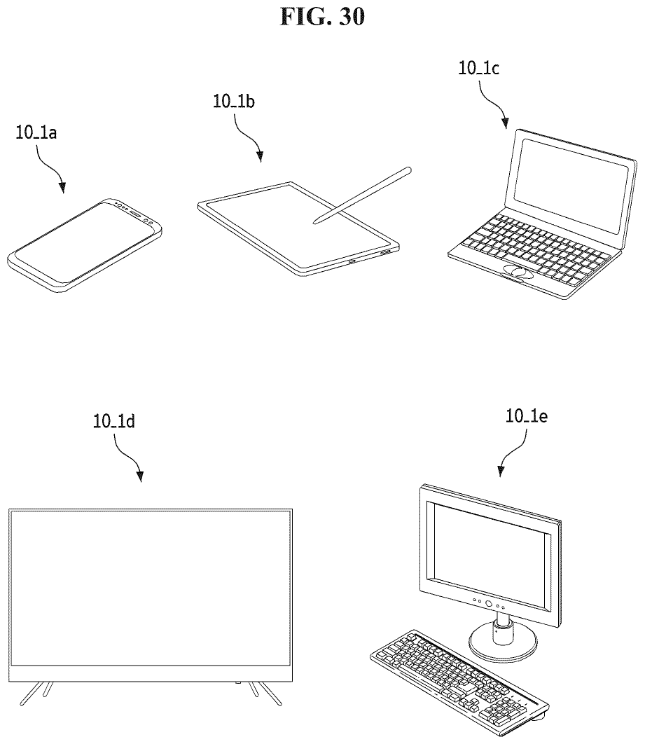

FIGS. 30, 31, and 32 are each a schematic diagram illustrating electronic devices according to one or more embodiments. FIGS. 30 through 32 illustrate examples of one or more suitable electronic devices to which a display device 10 according to one or more embodiments is applied.

FIG. 30 illustrates a smartphone 10_1a, a tablet PC 10_1b, a laptop 10_1c, a television 10_1d, and a desk monitor 10_1e as examples of electronic devices.

The smartphone 10_1a may include an input module such as a touch sensor and a communication module in addition to a display module 11. The smartphone 10_1a may process information received through the communication module or other input modules and display the information through the display module of the display device.

Like the smartphone 10_1a, the tablet PC 10_1b, the laptop 10_1c, the television 10_1d, and the desk monitor 10_1e may also include a display module and an input module and may further include a communication module in some cases.

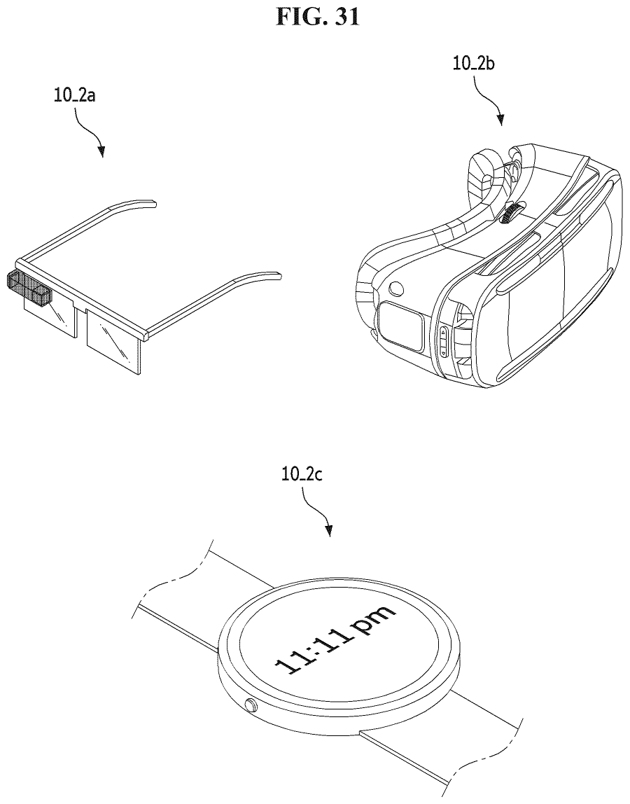

FIG. 31 illustrates embodiments in which an electronic device including a display module is applied to a wearable electronic device. The wearable electronic device may be smart glasses 10_2a, a head mounted display 10_2b, a smart watch 10_2c, and/or the like.

The smart glasses 10_2a and the head mounted display 10_2b may include a display module which outputs a display image and a reflector which provides the output display image to user's eyes by reflecting an output display screen. Accordingly, a screen of virtual reality or augmented reality may be provided to the user.

The smart watch 10_2c may include a biometric sensor as an input device and may provide biometric information recognized by the biometric sensor to a user through a display module.

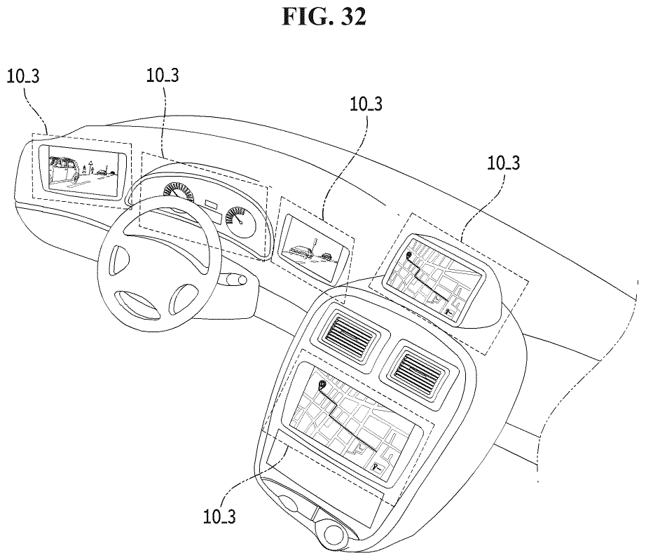

FIG. 32 illustrates embodiments in which an electronic device including a display module is applied to a vehicle. For example, an electronic device 10_3 may be applied to an instrument panel, center fascia, and/or the like of a vehicle, may be applied to a center information display (CID) located on a dashboard of the vehicle, or may be applied to a room mirror display replacing a side mirror.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display module, the display device, the electronic device/apparatus, the device-manufacturing apparatus, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In concluding the detailed description, those skilled in the art will appreciate that many variations and modifications may be made to the presented embodiments without substantially departing from the principles of the present disclosure. Therefore, the disclosed embodiments of the present disclosure are used in a generic and descriptive sense only and not for purposes of limitation. It is to be understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate;
an insulating layer on the substrate, and having a via hole in which a via electrode is located;
a connection electrode on the via electrode;
a reflective electrode on the connection electrode;
an optical auxiliary layer on the reflective electrode and the connection electrode;
a first electrode on the optical auxiliary layer and the connection electrode;
a pixel defining layer on the first electrode and the insulating layer to define an emission area exposing the first electrode;
a light emitting stack on the first electrode and the pixel defining layer; and
a second electrode on the light emitting stack,
wherein the optical auxiliary layer is on an upper surface of the reflective electrode and a side surface of the reflective electrode, and
the first electrode is on a side surface of the connection electrode to be connected to the side surface of the connection electrode.

2. The display device of claim 1,
wherein an edge of the optical auxiliary layer is on an edge of an upper surface of the connection electrode.

3. The display device of claim 1,
wherein the connection electrode and the optical auxiliary layer are around the reflective electrode.

4. The display device of claim 1,
wherein the optical auxiliary layer comprises a silicon oxide-based inorganic layer.

5. The display device of claim 1,
wherein the optical auxiliary layer has a different thickness for emission area to emit light of different colors.

6. The display device of claim 1,
further comprising a power connector connected to the second electrode.

7. The display device of claim 6,
wherein the power connector comprises:
a first power connection electrode connected to a power connection area;
a power buffer electrode on the first power connection electrode; and
a second power connection electrode on the power buffer electrode and connected to the second electrode.

8. The display device of claim 7,
wherein the power buffer electrode has a thickness equal to or smaller than 10 Å.

9. The display device of claim 7,
wherein the power buffer electrode is composed of a same material as the first electrode.

10. The display device of claim 7,
wherein the power buffer electrode comprises titanium nitride.

11. The display device of claim 1,
wherein a thickness of the first electrode on a side surface of the optical auxiliary layer is different from a thickness of the first electrode on an upper surface of the optical auxiliary layer.

12. The display device of claim 1,
wherein a thickness of the first electrode of a side surface of the optical auxiliary layer is smaller than a thickness of the first electrode on an upper surface of the optical auxiliary layer.

13. An electronic device comprising
a display device comprising a display screen,
wherein the display device further comprises:
a substrate;
an insulating layer on the substrate, and having a via hole in which a via electrode is located;
a connection electrode on the via electrode;
a reflective electrode on the connection electrode;
an optical auxiliary layer on the reflective electrode and the connection electrode;
a first electrode on the optical auxiliary layer and the connection electrode;
a pixel defining layer on the first electrode and the insulating layer to define an emission area exposing the first electrode;
a light emitting stack on the first electrode and the pixel defining layer; and
a second electrode on the light emitting stack,
wherein the optical auxiliary layer is on an upper surface of the reflective electrode and a side surface of the reflective electrode, and
the first electrode is on a side surface of the connection electrode to be connected to the side surface of the connection electrode.

14. The electronic device of claim 13,
wherein an edge of the optical auxiliary layer is on an edge of an upper surface of the connection electrode.

15. The electronic device of claim 13,
wherein the connection electrode and the optical auxiliary layer are around the reflective electrode.

16. The electronic device of claim 13,
wherein the electronic device comprises at least one of a smart phone, a tablet, a laptop, a television, a desk monitor, smart glasses, a smart watch, a head-mounted display, or a vehicle.

17. A method, comprising:
forming, on a substrate, an insulating layer on which via electrodes are located;
forming, on the insulating layer, a connection electrode layer connected to the via electrodes;
forming a reflective electrode layer on the connection electrode layer;
forming a buffer layer on the reflective electrode layer;
exposing the reflective electrode layer on the reflective electrode layer of a first subpixel, a second subpixel, and a third subpixel by patterning the buffer layer;
forming a first auxiliary layer on the reflective electrode layer;
forming a first auxiliary pattern on the reflective electrode layer of the third subpixel by patterning the first auxiliary layer;
forming a second auxiliary layer on the reflective electrode layer and the first auxiliary pattern;
forming a second auxiliary pattern on each of the reflective electrode layer of the second subpixel and the first auxiliary pattern of the third subpixel by patterning the second auxiliary layer;
forming a reflective electrode of the first subpixel on the connection electrode layer of the first subpixel, forming a reflective electrode of the second subpixel between the connection electrode layer of the second subpixel and the second auxiliary pattern of the second subpixel, and forming a reflective electrode of the third subpixel between the connection electrode layer of the third subpixel and the first auxiliary pattern of the third subpixel, by patterning the reflective electrode layer;
forming a third auxiliary layer on the reflective electrode, the connection electrode layer, and the second auxiliary pattern;
forming connection electrodes of the first to third subpixels and forming a third auxiliary pattern on each of the reflective electrode of the first subpixel, the second auxiliary pattern of the second subpixel, and the second auxiliary pattern of the third subpixel by patterning the connection electrode layer and the third auxiliary layer, thereby forming optical auxiliary layers having different thicknesses in the first to third subpixels and covering an upper surface and a side surface of each reflective electrode;
forming a first electrode layer on the optical auxiliary layers and the insulating layer;
forming first electrodes on each upper surface of the optical auxiliary layers, each side surface of the optical auxiliary layers, and each side surface of the connection electrodes, by patterning the first electrode layer;
forming a defining layer on the first electrodes and the insulating layer; and
washing the substrate comprising the first electrodes,
wherein the method is a method for fabricating a display device.

18. The method of claim 17, further comprising:
forming an intermediate layer on a side surface of the defining layer;
forming a first bank layer on the defining layer and the intermediate layer;
forming, on the first bank layer, a second bank layer having an etch rate higher than an etch rate of the first bank layer;
forming, on the second bank layer, a third bank layer having an etch rate lower than an etch rate of the second bank layer;
forming a second bank and a third bank having a reverse tapered shape by patterning the second bank layer and the third bank layer, and exposing the first bank layer;
forming a pixel defining layer defining emission areas exposing the first electrodes, forming a planarization layer on the pixel defining layer, and forming a first bank on the pixel defining layer and the planarization layer by patterning the defining layer, the intermediate layer, and the first bank layer;
forming a light emitting stack on the first electrodes, the pixel defining layer, and the planarization layer, and the third bank; and
forming a second electrode on the light emitting stack.

19. The method of claim 17,
wherein, when the buffer layer is patterned, a power buffer electrode is formed on the reflective electrode layer of a first power connection area.

20. The method of claim 17,
wherein the first auxiliary layer, the second auxiliary layer, and the third auxiliary layer are deposited through an atomic layer deposition method.
